(19) United States
(12) Patent Application Publication
(10) Pub. No.: US 2019/0326915 A1
(43) Pub. Date: Oct. 24, 2019

(54) Sampling Phase-Locked Loop (PLL)

(71) Applicant: Qualcomm Incorporated, San Diego, CA (US)

(72) Inventors: Masoud Moslehi Bajestan, San Diego, CA (US); Mehran Mohammadi Izad, San Diego, CA (US); Marco Zanuso, Encinitas, CA (US)

(21) Appl. No.: 15/957,441

(22) Filed: Apr. 19, 2018

(51) Int. Cl. H03L 7/089; H03L 7/099

(52) U.S. Cl. CPC H03L 7/0895; H03L 7/099

(57) ABSTRACT

An apparatus is disclosed that implements a sampling phase-locked loop. In an example aspect, the apparatus includes a phase frequency detector, a relative phase signal determiner, a voltage-controlled oscillator (VCO), and a feedback path. The phase frequency detector is configured to produce a phase indication signal based on a reference signal and a feedback signal. The relative phase signal determiner is coupled to the phase frequency detector and includes a sampler. The relative phase signal determiner is configured to determine a relative phase signal based on the phase indication signal using the sampler. The VCO is coupled to the relative phase signal determiner and is configured to produce an oscillating signal based on the relative phase signal. The feedback path is disposed between the VCO and the phase frequency detector. The feedback path is configured to provide the feedback signal to the phase frequency detector using the oscillating signal.

### TECHNICAL FIELD

This disclosure relates generally to electronic communications and, more specifically, to facilitating the use of communication signals having different frequencies with a phase-locked loop (PLL) that utilizes sampling.

### BACKGROUND

Electronic devices include traditional computing devices such as desktop computers, notebook computers, smartphones, wearable devices like a smartwatch, internet servers, and so forth. However, electronic devices also include other types of computing devices such as personal voice assistants, thermostats, automotive electronics, robotics, devices embedded in other machines like refrigerators and industrial tools, Internet-of-Things (IoT) devices, and the like. These various electronic devices provide information, entertainment, social interaction, security, safety, productivity, transportation, and other services to human users. Thus, electronic devices play crucial roles in many aspects of modern society.

Many of the services provided by electronic devices in today's interconnected world depend at least partly on electronic communications. Electronic communications can include those exchanged between or among distributed electronic devices using wireless or wired signals that are transmitted over one or more networks, such as the Internet or a cellular network. Electronic communications can also include those exchanged between or among different printed circuit boards, modules, chips, or even cores of a given integrated circuit that are within a single electronic device. Regardless, electronic communications are usually accomplished by generating or propagating signals. Such electronic communications are typically performed using at least one signal that is designed to have a specified frequency. Generally, communication signals are more likely to be correctly transmitted and received, as well as properly interpreted, if the specified frequency is accurately created and reliably maintained.

A phase-locked loop (PLL) is often used to create, or synthesize, a desired frequency. In fact, a phase-locked loop is typically a core part of a frequency synthesizer, which is a component that is employed by electronic devices to synthesize signals having different frequencies. In operation, a phase-locked loop receives a reference signal and applies the reference signal to a feedback loop. Using the feedback loop, the circuitry of the phase-locked loop generates an output signal that oscillates at a desired frequency in a stable and accurate manner. Typically, the phase-locked loop derives the frequency of the oscillating output signal from the reference signal, such as by being some multiple of the reference signal.

A PLL-based frequency synthesizer thus outputs an oscillating signal having some desired frequency. The electronic device then uses the synthesized frequency of the oscillating output signal in one or more stages of a communication scenario. Example stages for communicating an electromagnetic signal include generating, transmitting, receiving, or interpreting a communication signal. In an example signal-generation stage, a frequency generated by a phase-locked loop can be used to modulate a communication signal. Here, the modulation entails adding information—such as a text and an associated photograph—to the communication signal. In an example signal-transmission stage, the frequency generated by a phase-locked loop can be employed to upconvert a frequency of a communication signal using a mixer. With an up-conversion operation, the mixer increases the frequency of the communication signal, such as to enable the communication signal to be transmitted wirelessly as a radio frequency (RF) signal.

A phase-locked loop can also be used on a receiving side of a typical communication scenario. For instance, a phase-locked loop can be used to down-convert a frequency of a received communication signal or to demodulate the received communication signal to recover the encoded information, such as the text message along with the associated photograph. Further, a phase-locked loop can be used to produce a clock signal that controls a rate of operation of circuitry on an integrated circuit, such as a system-on-chip (SoC) that processes a communication or other data.

Thus, phase-locked loops are employed in multiple stages of a given communication scenario to support electronic communication with electronic devices. Consequently, electrical engineers and other designers of electronic devices strive to improve the functionality and usability of phase-locked loops to facilitate electronic communication with electronic devices.

### SUMMARY

A phase-locked loop (PLL) that uses sampling, or a sampling phase-locked loop (PLL), is disclosed herein. Example implementations of the disclosed sampling phase-locked loop produce less noise than a traditional phase-locked loop and can omit an auxiliary frequency-locked loop. Described implementations can be used to facilitate modulating a communication signal with information, upconverting a frequency of a communication signal to be transmitted, down-converting a frequency of a received communication signal, or demodulating a down-converted communication signal to recover information. The described sampling phase-locked loop can also be used in other scenarios, such as for controlling a rate of data processing with a clock signal.

In an example aspect, an integrated circuit is disclosed. The integrated circuit includes a phase frequency detector, a relative phase signal determiner, a voltage-controlled oscillator, and a feedback path. The phase frequency detector is configured to produce a phase indication signal based on a reference signal and a feedback signal. The relative phase signal determiner is coupled to the phase frequency detector and includes a sampler. The relative phase signal determiner is configured to determine a relative phase signal based on the phase indication signal using the sampler. The voltage-controlled oscillator is coupled to the relative phase signal determiner and is configured to produce an oscillating signal based on the relative phase signal. The feedback path is disposed between the voltage-controlled oscillator and the phase frequency detector. The feedback path is configured to provide the feedback signal to the phase frequency detector using the oscillating signal.

In an example aspect, an electronic device is disclosed. The electronic device includes a phase frequency detector, a voltage-controlled oscillator, and a feedback path. The phase frequency detector is configured to produce a phase indication signal based on a phase difference between a reference signal and a feedback signal. The electronic device also includes current means for generating a charge signal responsive to the phase indication signal, with the charge signal including a substantially-continuous positive current responsive to the phase indication signal representing a positive phase difference. The current means is coupled to the phase frequency detector. The voltage-controlled oscillator is coupled to the current means and is configured to produce an oscillating signal based on the charge signal. The feedback path is disposed between the voltage-controlled oscillator and the phase frequency detector. The feedback path is configured to provide the feedback signal to the phase frequency detector using the oscillating signal.

In an example aspect, a method for operating a sampling phase-locked loop is disclosed. The method includes producing a phase indication signal based on a phase difference between a reference signal and a feedback signal of the sampling phase-locked loop. The method also includes generating a slope signal based on the phase indication signal, the slope signal indicative of whether the phase difference is positive or negative. The method additionally includes sampling the slope signal to secure a sampled signal and amplifying the sampled signal to create a charge signal. The method further includes filtering the charge signal to provide a voltage signal and producing the feedback signal based on the voltage signal.

In an example aspect, a sampling phase-locked loop is disclosed. The sampling phase-locked loop includes a phase frequency detector, a slope generator, a slope sampler, and a transconductance amplifier. The sampling phase-locked loop further includes a loop filter, a voltage-controlled oscillator, and a feedback path. The phase frequency detector is configured to produce a phase indication signal based on a reference signal and a feedback signal. The slope generator is coupled to the phase frequency detector and configured to generate a slope signal based on the phase indication signal. The slope sampler is coupled to the slope generator and configured to secure a sampled signal from the slope signal. The transconductance amplifier is coupled to the slope sampler and configured to create a charge signal based on the sampled signal. The loop filter is coupled to the transconductance amplifier and configured to provide a voltage signal based on the charge signal. The voltage-controlled oscillator is coupled to the loop filter and configured to produce an oscillating signal based on the voltage signal. The feedback path is disposed between the voltage-controlled oscillator and the phase frequency detector, with the feedback path configured to provide the feedback signal to the phase frequency detector using the oscillating signal.

### BRIEF DESCRIPTION OF DRAWINGS

FIG. 1 illustrates an example environment that includes a wireless transceiver in which a phase-locked loop (PLL) with sampling, or a sampling PLL, can be implemented.

FIG. 2 illustrates an example wireless transceiver that includes a frequency synthesizer in which a sampling phase-locked loop can be implemented to operate in conjunction with, e.g., a mixer in a transmit chain.

FIG. 3 illustrates an example sampling phase-locked loop including a phase frequency detector, a charge signal generator having a relative phase signal determiner and an amplifier, a loop filter, a voltage-controlled oscillator, and a feedback path having a frequency divider.

FIG. 4-1 illustrates a graph of current versus phase difference, which depicts an example charge signal at an output of a charge signal generator versus a phase difference between a reference signal and a feedback signal, for example implementations that are described herein for a sampling phase-locked loop having a phase frequency detector in conjunction with a sampler.

FIG. 4-2 illustrates a graph of current versus phase difference for a phase-locked loop having a phase frequency detector in conjunction with a charge pump.

FIG. 5 illustrates an example sampling phase-locked loop that includes a relative phase signal determiner realized with a slope generator and a slope sampler and that includes an amplifier implemented as a transconductance amplifier.

FIG. 6 illustrates example circuitry for a phase frequency detector.

FIG. 7 illustrates example circuitry for a slope generator.

FIG. 8 illustrates example circuitry for a slope sampler.

FIG. 9 illustrates example circuitry for a transconductance (Gm) amplifier and example circuitry for a loop filter.

FIG. 10-1 illustrates an example signal timing diagram for a situation in which a reference signal leads a feedback signal.

FIG. 10-2 illustrates an example signal timing diagram for a situation in which the reference signal is substantially phase-locked to the feedback signal.

FIG. 10-3 illustrates an example signal timing diagram for a situation in which the reference signal lags the feedback signal.

FIG. 11 illustrates an example calibration mode in which a slope generator can be calibrated by a loop calibrator.

FIG. 12 illustrates an example signal timing diagram for a calibration mode implemented by the slope generator and the loop calibrator.

FIG. 13 is a flow diagram illustrating an example process for operating a sampling phase-locked loop.

FIG. 14 illustrates an example electronic device that includes an integrated circuit in which a sampling phase-locked loop can be implemented.

### DETAILED DESCRIPTION

Generally, electronic communications are made using signals that oscillate at different frequencies. Electronic devices use frequency synthesizers to create signals having different frequencies, and many frequency synthesizers include a phase-locked loop (PLL) to generate a desired frequency. Further, phase-locked loops are often used to generate clock signals that control the timing of processing operations in integrated circuits, such a central processor unit (CPU), a graphics processing unit (GPU), or a system-on-chip (SoC). Phase-locked loops are therefore instrumental in facilitating our modern interconnected society. However, “traditional” phase-locked loops have a number of issues.

A traditional phase-locked loop includes a number of components distributed around a loop with a feedback control system. These components typically include a phase frequency detector, a charge pump, a loop filter, and a voltage-controlled oscillator, which outputs an oscillating signal. To implement the feedback control system, the oscillating signal is fed back to the phase frequency detector in accordance with a frequency divider value. The phase frequency detector compares this feedback signal to a reference signal. The charge pump, which receives an output from the phase frequency detector, introduces an appreciable level of noise into the traditional phase-locked loop. This noise affects the oscillating signal output. Furthermore, the feedback control system multiplies the noise level exponentially based on the frequency divider value. As the frequencies of communication signals and clock signals continue to increase into the gigahertz (GHz) or 10 s of GHz range, the frequency divider value can also increase, which exacerbates the impact of the noise.

To reduce the level of noise that is generated internally by a phase-locked loop circuit, sampling phase-locked loops were developed. A sampling phase-locked loop can omit one or more components of the traditional phase-locked loop by sampling some version of the oscillating signal that is output by the voltage-controlled oscillator or by sampling another signal that is derived from this oscillating signal output. For example, the charge pump can be omitted from a sampling phase-locked loop, which enables the sampling phase-locked loop to be used in applications that benefit from lower phase noise levels. A number of sampling phase-locked loop designs have been presented. However, these existing sampling architectures utilize an auxiliary frequency-locked loop, which causes new design challenges. First, the auxiliary frequency-locked loop causes stability issues that introduce uncertainty and the potential for processing errors. Second, even if the frequency-locked loop works correctly, the locking time is extended, which causes operational delays, especially each time the sampling phase-locked loop is responsible for locking to a new frequency. Furthermore, existing sampling phase-locked loops have loop bandwidths that vary over different process-voltage-temperature (PVT) conditions.

To address these issues, sampling phase-locked loop implementations that are described herein can avoid employing an auxiliary frequency-locked loop. With a sampling phase-locked loop, a frequency of a reference signal is used as a basis to produce an oscillating signal. A phase frequency detector receives the reference signal and a feedback signal. An output of the phase frequency detector is analyzed or manipulated to generate a relative phase signal indicative of a phase difference between the reference signal and the feedback signal. For example, a slope generator can use the output of the phase frequency detector to generate a slope signal, which indicates whether the reference signal leads or lags the feedback signal. A slope sampler samples the slope signal to produce a sampled signal. The slope signal and the sampled signal can be implemented with differential signaling. The sampled signal is routed to an oscillator of the sampling phase-locked loop. For instance, in some implementations, the sampled signal is routed through an amplifier, to a filter, and then to a voltage-controlled oscillator. The voltage-controlled oscillator produces the oscillating signal. A version of the oscillating signal is routed through a feedback path to the phase frequency detector as the feedback signal.

In these manners, a noise level of a phase-locked loop can be reduced by using a sampling phase-locked loop. With a sampling phase-locked loop, the sampler provides a relatively high phase-detection gain that significantly suppresses the noise of loop components following the phase frequency detector. Described implementations of a sampling phase-locked loop can provide increased stability and faster settling times without relying on an additional frequency-locked loop by including a phase frequency detector before a sampler in a feedback loop of the sampling phase-locked loop. Further, the bandwidth of the sampling phase-locked loop can be maintained substantially constant over different PVT conditions by employing a transconductance amplifier (e.g., a Gm-cell) with a constant-Gm bias and by using a resistor-capacitor (RC) calibration loop. Further, a differential sampling technique for the interface between the slope signal and the sampling signal provides a low reference spur level as described herein.

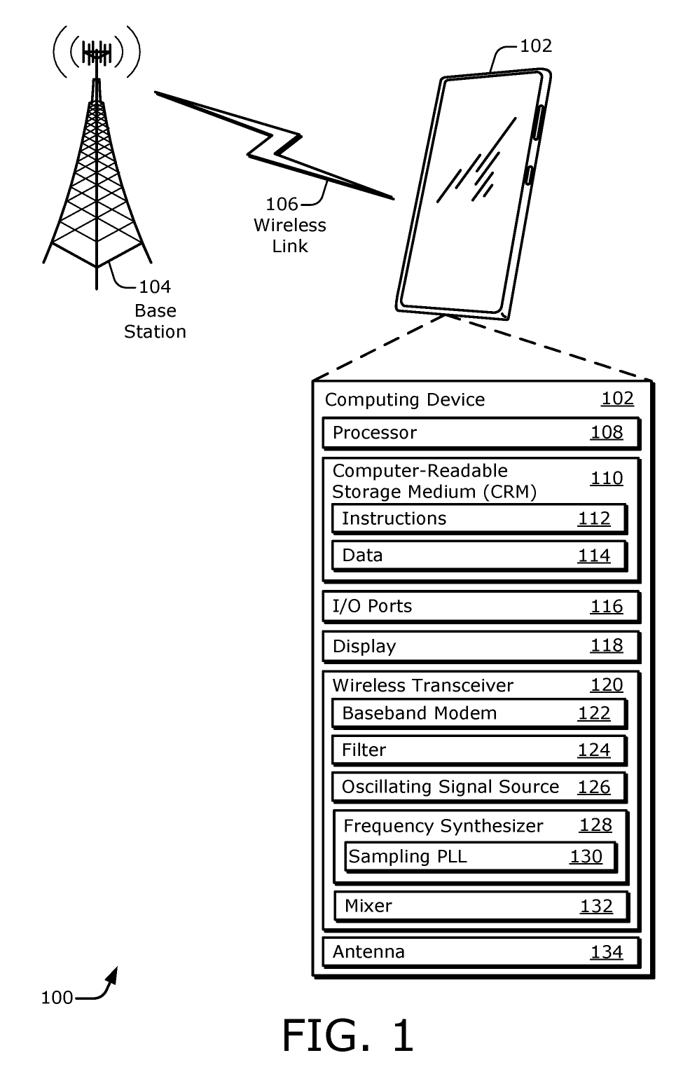

FIG. 1 illustrates an example environment 100 that includes a wireless transceiver 120 in which a sampling phase-locked loop 130 can be implemented. The example environment 100 includes a computing device 102 that communicates with a base station 104 through a wireless communication link 106 (wireless link 106). In this example, the computing device 102 is implemented as a smart phone. However, the computing device 102 may be implemented as any suitable computing or other electronic device, such as a modem, cellular base station, broadband router, access point, cellular phone, gaming device, navigation device, media device, laptop computer, desktop computer, tablet computer, server, network-attached storage (NAS) device, smart appliance, vehicle-based communication system, Internet-of-Things (IoT) device, and so forth.

The base station 104 communicates with the computing device 102 via the wireless link 106, which may be implemented as any suitable type of wireless link. Although depicted as a base station tower of a cellular radio network, the base station 104 may represent or be implemented as another device, such as a satellite, cable television head-end, terrestrial television broadcast tower, access point, peer-to-peer device, mesh network node, fiber optic line, another electronic device generally, and so forth. Hence, the computing device 102 may communicate with the base station 104 or another device via a wired connection, a wireless connection, or a combination thereof.

The wireless link 106 can include a downlink of data or control information communicated from the base station 104 to the computing device 102 and an uplink of other data or control information communicated from the computing device 102 to the base station 104. The wireless link 106 may be implemented using any suitable communication protocol or standard, such as 3rd Generation Partnership Project Long-Term Evolution (3GPP LTE), IEEE 802.11, IEEE 802.16, Bluetooth™, and so forth.

The computing device 102 includes a processor 108 and a computer-readable storage medium 110 (CRM 110). The processor 108 may include any type of processor, such as an application processor or a multi-core processor, that is configured to execute processor-executable instructions (e.g., code) stored by the CRM 110. The CRM 110 may include any suitable type of data storage media, such as volatile memory (e.g., random access memory (RAM)), non-volatile memory (e.g., Flash memory), optical media, magnetic media (e.g., disk or tape), and so forth. In the context of this disclosure, the CRM 110 is implemented to store instructions 112, data 114, and other information of the computing device 102, and thus does not include transitory propagating signals or carrier waves.

The computing device 102 may also include input/output ports 116 (I/O ports 116) or a display 118. The I/O ports 116 enable data exchanges or interaction with other devices, networks, or users. The I/O ports 116 may include serial ports (e.g., universal serial bus (USB) ports), parallel ports, audio ports, infrared (IR) ports, and so forth. The display 118 can be realized as a screen or projection that presents graphics of the computing device 102, such as a user interface associated with an operating system, program, or application. Alternatively or additionally, the display 118 may be implemented as a display port or virtual interface through which graphical content of the computing device 102 is communicated or presented.

For communication purposes, the computing device 102 also includes a wireless transceiver 120 and an antenna 134. The wireless transceiver 120 provides connectivity to respective networks and other electronic devices connected therewith. Additionally or alternatively, the computing device 102 may include a wired transceiver, such as an Ethernet or fiber optic interface for communicating over a personal or local network, an intranet, or the Internet. The wireless transceiver 120 may facilitate communication over any suitable type of wireless network, such as a wireless local area network (LAN) (WLAN), a peer-to-peer (P2P) network, a mesh network, a cellular network, a wireless wide-area-network (WWAN), and/or a wireless personal-area-network (WPAN). In the context of the example environment 100, the wireless transceiver 120 enables the computing device 102 to communicate with the base station 104 and networks connected therewith.

The wireless transceiver 120 can include circuitry, logic, and other hardware for transmitting or receiving a wireless signal for at least one communication frequency band. In operation, the wireless transceiver 120 can implement at least one, e.g., radio frequency (RF) transceiver to process data and/or signals associated with communicating data of the computing device 102 via the antenna 134. As shown, the wireless transceiver 120 includes at least one baseband modem 122. The baseband modem 122 may be implemented as a system on-chip (SoC) that provides a digital communication interface for data, voice, messaging, and other applications of the computing device 102. The baseband modem 122 may also include baseband circuitry to perform high-rate sampling processes that can include analog-to-digital conversion (ADC), digital-to-analog conversion (DAC), gain correction, skew correction, frequency translation, and so forth. Alternatively, the baseband modem 122 may be implemented separately from the wireless transceiver 120.

Generally, the wireless transceiver 120 can include band-pass filters, switches, amplifiers, and so forth for routing and conditioning signals that are transmitted or received via the antenna 134. As shown, the wireless transceiver 120 also includes at least one filter 124, at least one oscillating signal source 126, at least one frequency synthesizer 128, and at least one mixer 132. Here, the frequency synthesizer 128 includes at least one sampling phase-locked loop 130 (Sampling PLL 130). In operation, the wireless transceiver 120 can provide some measure of attenuation for wireless signals at different frequencies using the filter 124. The frequency synthesizer 128, using the oscillating signal source 126 and the sampling phase-locked loop 130, can synthesize signals having one or more different frequencies. The wireless transceiver 120 can further perform frequency conversion using a synthesized signal and the mixer 132, which may include an upconverter and/or a downconverter that performs frequency conversion in a single conversion step, or through multiple conversion steps. The wireless transceiver 120 may also include logic to perform in-phase/quadrature (I/Q) operations, such as synthesis, encoding, modulation, demodulation, and decoding using a synthesized signal.

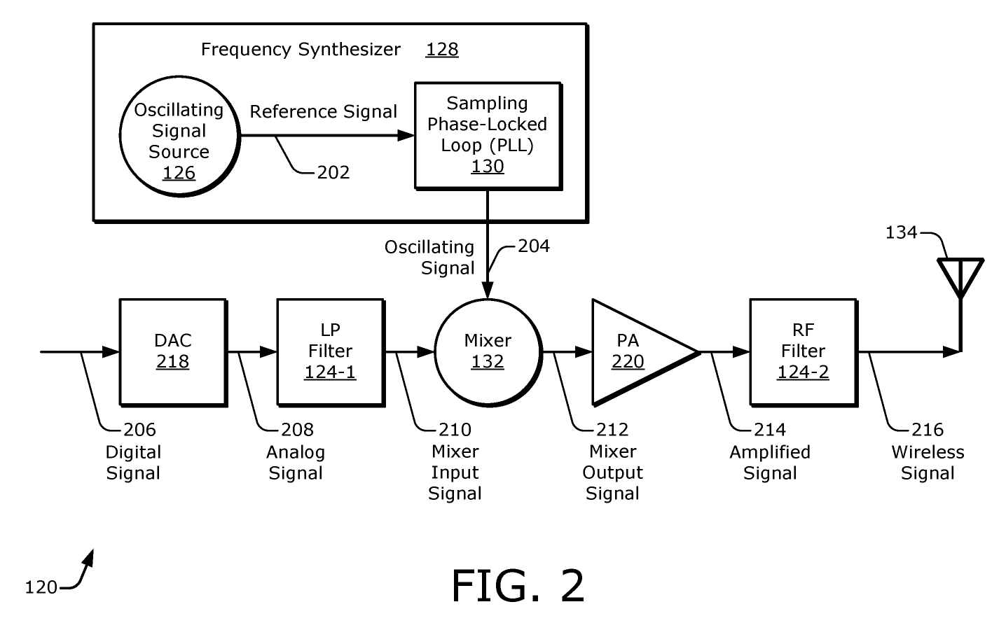

In some cases, components of the wireless transceiver 120 are implemented as separate receiver and transmitter entities. Additionally or alternatively, the wireless transceiver 120 can be realized using multiple or different sections to implement respective receiving and transmitting operations (e.g., using separate transmit and receive chains). Example operations of, as well as interactions between, the filter 124, the oscillating signal source 126, the frequency synthesizer 128—including the sampling phase-locked loop 130, and the mixer 132 are described with reference to FIG. 2. The sampling phase-locked loop 130 can at least partially implement a phase-locked loop having a phase frequency detector coupled in series with a sampler as described herein.

FIG. 2 illustrates an example of the wireless transceiver 120 that includes the frequency synthesizer 128 in which a phase-locked loop with a sampler—e.g., a sampling phase-locked loop 130—can be realized. The sampling phase-locked loop 130 can be implemented to operate in conjunction with the mixer 132, e.g., in a transmit chain (as shown) or in a receive chain. The example components of the wireless transceiver 120 are depicted in two rows: an upper row and a lower row. The upper row includes the oscillating signal source 126 and the sampling phase-locked loop 130, which are both shown to be part of the frequency synthesizer 128. From left-to-right, the lower row includes a digital-to-analog converter 218 (DAC 218), a low-pass filter 124-1 (LP filter 124-1), the mixer 132, a power amplifier 220 (PA 220), an RF filter 124-2, and the antenna 134.

In example implementations, for the upper row, the oscillating signal source 126 produces a reference signal 202. The reference signal 202 can oscillate at one or more frequencies for one or more purposes. For instance, the oscillating signal source 126 can be realized as a clock signal source, and the reference signal 202 can be realized as a clock signal. The oscillating signal source 126 can include an oscillator (e.g., a crystal oscillator) that generates a reference signal 202, can strengthen or condition a reference signal 202 received from another component, can change a frequency of a received reference signal 202, can selectively gate or release an incoming reference signal 202, some combination thereof, and so forth. Although the oscillating signal source 126 is illustrated as being part of the frequency synthesizer 128 in FIG. 2, the oscillating signal source 126 may alternatively be separate from the frequency synthesizer 128 (e.g., as shown in FIG. 1) or be part of the sampling phase-locked loop 130. Regardless, the oscillating signal source 126 is coupled to the phase-locked loop 130 or otherwise can provide the reference signal 202 to the sampling phase-locked loop 130.

Thus, the sampling phase-locked loop 130 is coupled to the oscillating signal source 126 to receive the reference signal 202 as an input signal at an input node thereof. The sampling phase-locked loop 130 generates one or more oscillating signals that can have different frequencies based on the reference signal 202. To do so, the sampling phase-locked loop 130 can lock onto and track a frequency, as well as a phase, of the reference signal 202 to produce at least one oscillating signal 204. In operation, the sampling phase-locked loop 130 can generate an oscillating signal 204 having a frequency that is, for instance, some multiple of a frequency of the reference signal 202. The sampling phase-locked loop 130 can therefore provide the oscillating signal 204 as a frequency-synthesizer output signal to the mixer 132. The mixer 132 can use the oscillating signal 204 to upconvert a lower-frequency mixer input signal 210 to a higher-frequency mixer output signal 212 for subsequent transmission by the transmit chain. For example, the mixer 132 can upconvert the mixer input signal 210 from a baseband frequency to an RF frequency. This mixer input signal 210, and the mixing thereof, is described with reference to the lower row that is depicted in FIG. 2.

In the lower row, the digital-to-analog converter 218 receives a digital signal 206, such as from the baseband modem 122 of FIG. 1. The digital-to-analog converter 218 performs a digital-to-analog conversion and produces an analog signal 208 based on the digital signal 206. The digital-to-analog converter 218 is coupled to the low-pass filter 124-1 and provides the analog signal 208 to the low-pass filter 124-1. The low-pass filter 124-1 performs a low-pass filtering operation by attenuating frequencies of the analog signal 208 that are above some cutoff frequency to produce a mixer input signal 210. The low-pass filter 124-1 is coupled to the mixer 132 and provides the mixer input signal 210 to the mixer 132.

The mixer 132 is coupled to the low-pass filter 124-1 and receives the mixer input signal 210 from the low-pass filter 124-1. The mixer 132 performs an upconverting operation to facilitate an RF transmission from the wireless transceiver 120. To do so, the mixer 132 mixes the mixer input signal 210 with at least one higher-frequency signal, such as the oscillating signal 204 received from the sampling phase-locked loop 130. As a result of the mixing up-conversion operation, the mixer 132 produces a mixer output signal 212 that has a higher frequency than that of the mixer input signal 210 using the oscillating signal 204. The mixer 132 is coupled to the power amplifier 220 and provides the mixer output signal 212 to the power amplifier 220.

The power amplifier 220 amplifies the mixer output signal 212 to produce an amplified signal 214 having more power to emanate from the antenna 134. The power amplifier 220 is coupled to the RF filter 124-2 and provides the amplified signal 214 to the RF filter 124-2. The RF filter 124-2 filters the amplified signal 214 to accommodate the intended communication frequency band to produce a wireless signal 216. The RF filter 124-2 is coupled to the antenna 134 and provides the wireless signal 216 to the antenna 134 for transmission. The antenna 134 can then emanate the wireless signal 216 from the wireless transceiver 120 via the wireless link 106 of FIG. 1. Although the sampling phase-locked loop 130 is shown in the context of a transmit chain of the wireless transceiver 120, a sampling phase-locked loop 130 as described herein can be employed in a receive chain of a wireless transceiver 120, as well as in alternative environments and other usage scenarios.

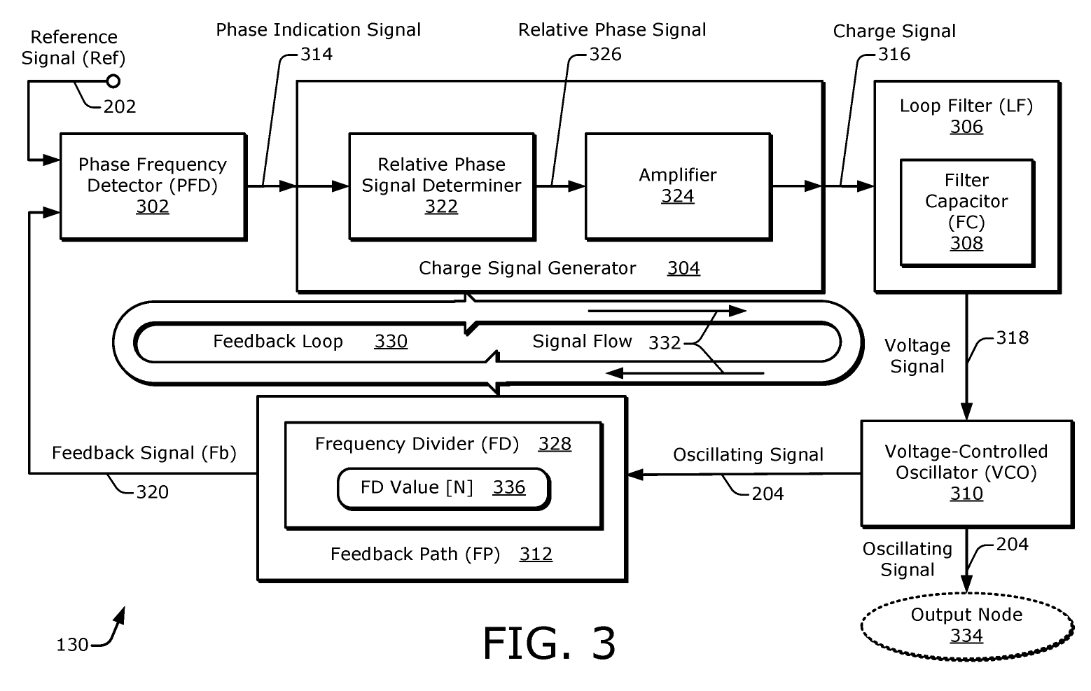

FIG. 3 illustrates an example sampling phase-locked loop 130 including a phase frequency detector 302 (PFD), a charge signal generator 304, a loop filter 306 (LF), a voltage-controlled oscillator 310 (VCO), and a feedback path 312 (FP). As shown, the charge signal generator 304 includes a relative phase signal determiner 322 and an amplifier 324. The loop filter 306 includes a filter capacitor 308 (FC), and the feedback path 312 includes a frequency divider 328 (FD). The feedback path 312 extends from the voltage-controlled oscillator 310 to the phase frequency detector 302.

In example implementations, the sampling phase-locked loop 130 defines a feedback loop 330 that includes two or more of the illustrated components, such as the phase frequency detector 302, the relative phase signal determiner 322, the voltage-controlled oscillator 310, and the feedback path 312. These components are coupled together in series along the feedback loop 330. In an example operation, the sampling phase-locked loop 130 is configured to establish a signal flow 332 around the feedback loop 330 (e.g., in a clockwise direction as depicted). At least a portion of the signal flow 332 traverses, for instance, from the phase frequency detector 302, through the relative phase signal determiner 322, and to the voltage-controlled oscillator 310.

As shown, the phase frequency detector 302 is coupled to the charge signal generator 304, and the charge signal generator 304 is coupled to the loop filter 306. More specifically, the phase frequency detector 302 is coupled to the relative phase signal determiner 322, and the relative phase signal determiner 322 is coupled to the amplifier 324. The amplifier 324 is coupled to the loop filter 306. Thus, the relative phase signal determiner 322 and the amplifier 324 are coupled between the phase frequency detector 302 and the loop filter 306. The loop filter 306 is coupled to the voltage-controlled oscillator 310, and the voltage-controlled oscillator 310 is coupled to the frequency divider 328 along the feedback path 312. To close or complete the feedback loop 330 of the sampling phase-locked loop 130, and to enable the signal flow 332 to propagate around the feedback loop 330, the frequency divider 328 is coupled to the phase frequency detector 302.

In example implementations, the sampling phase-locked loop 130 utilizes a negative feedback path as part of the signal flow 332 of the feedback loop 330. The following description of the feedback loop 330 of the sampling phase-locked loop 130 starts at the top-left corner of FIG. 3 at the phase frequency detector 302 and continues in a clockwise direction. The phase frequency detector 302 receives a feedback signal 320 (Fb) via the feedback path 312 and the reference signal 202 (Ref) via an input node (not explicitly shown). From the phase frequency detector 302, the signal flow 332 of the sampling phase-locked loop 130 continues along the serially-coupled components to the relative phase signal determiner 322. From the relative phase signal determiner 322, the signal flow 332 extends through the amplifier 324 to the loop filter 306. The loop filter 306 provides a control signal in the form of a voltage signal 318 to the voltage-controlled oscillator 310. The voltage-controlled oscillator 310 produces an output signal in the form of an oscillating signal 204 at an output node 334 of the sampling phase-locked loop 130. The oscillating signal 204 is also fed back to the phase frequency detector 302 using the feedback path 312, which may include the frequency divider 328.

In an example operation, the phase frequency detector 302 produces a phase indication signal 314 based on a phase difference between the reference signal 202 and the feedback signal 320. The phase indication signal 314 may include, for example, an up signal or a down signal. The relative phase signal determiner 322 receives the phase indication signal 314, which is indicative of the detected phase difference, and the reference signal 202. The relative phase signal determiner 322 converts the phase indication signal 314 to a relative phase signal 326. To do so, the relative phase signal determiner 322 can use the phase indication signal 314 and the reference signal 202 to determine if the reference signal 202 leads or lags (or is substantially locked with) the feedback signal 320. The relative phase signal determiner 322 uses a sampler to encode this lead versus lag versus lock information into the relative phase signal 326, which can be implemented with differential signaling, as is described below. In these manners, the relative phase signal determiner 322 can provide a mechanism for determining a relative phase signal 326 based on the phase indication signal 314.

The relative phase signal determiner 322 provides the relative phase signal 326 to the amplifier 324. Responsive to the relative phase signal 326, the amplifier 324 produces a charge signal 316, which is provided to the loop filter 306. The charge signal 316 can be realized by the amplifier 324 as a positive current or a negative current to increase or decrease a charge at, and thus a voltage across, the filter capacitor 308. In these manners, the amplifier 324 can provide a mechanism for amplifying the relative phase signal 326 to produce the charge signal 316. The voltage across the filter capacitor 308 can be provided to the voltage-controlled oscillator 310 as the voltage signal 318. In effect, the loop filter 306 uses the filter capacitor 308 to integrate the current of the charge signal 316 by charging the filter capacitor 308 (e.g., in which charging can include adding charge to or removing charge from the filter capacitor 308). The loop filter 306 can also perform a low-pass filtering as part of the operation to generate the voltage signal 318.

Thus, the loop filter 306 provides the voltage signal 318 to the voltage-controlled oscillator 310. The voltage-controlled oscillator 310 functions as an oscillator having a frequency that is proportional to a magnitude of the voltage signal 318. Hence, the voltage-controlled oscillator 310 produces the oscillating signal 204 based on the voltage signal 318 obtained from the loop filter 306. The oscillating signal 204 can represent an output signal of the sampling phase-locked loop 130 at the output node 334. The oscillating signal 204 is also used to continue the feedback loop 330 of the sampling phase-locked loop 130. In some implementations, the oscillating signal 204 can be fed back to the phase frequency detector 302 via the feedback path 312 without modification (e.g., where the feedback signal 320 comprises an unmodified version of the oscillating signal 204).

As illustrated in FIG. 3, the voltage-controlled oscillator 310 provides the oscillating signal 204 to the frequency divider 328. The frequency divider 328 operates based on a frequency divider value 336 of “N,” which can represent some positive integer equal to or greater than one. The frequency divider 328 generates the feedback signal 320 based on the oscillating signal 204 and the frequency divider value 336, which can be fixed or adjustable. For example, the frequency divider 328 can be configured to provide the feedback signal 320 to the phase frequency detector 302 by applying a frequency divider value 336 to the oscillating signal 204. The frequency divider 328 provides the feedback signal 320 to the phase frequency detector 302 to complete the feedback loop 330 of the sampling phase-locked loop 130.

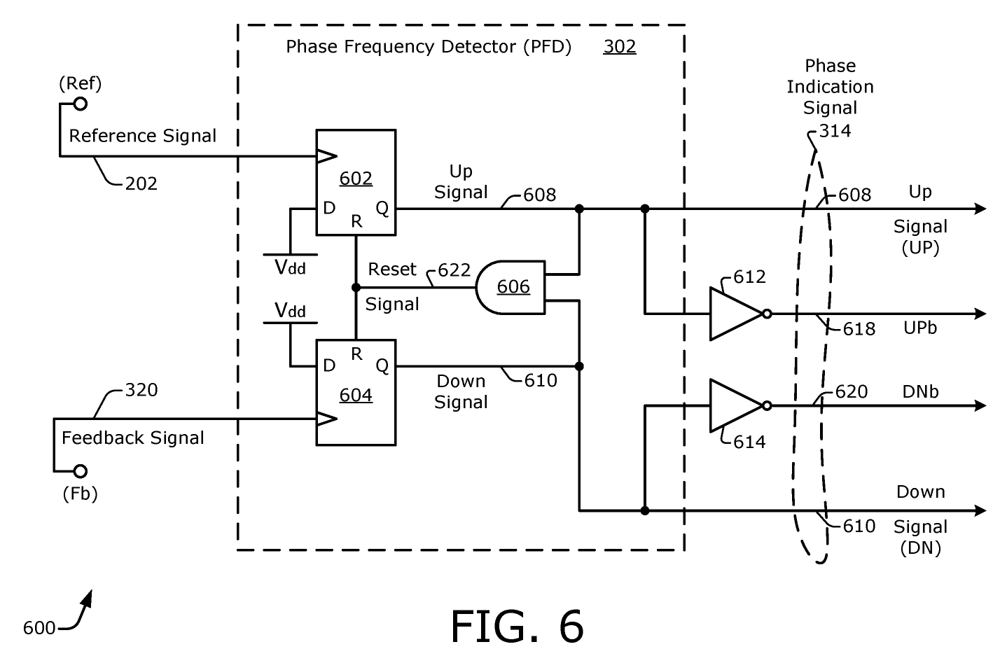

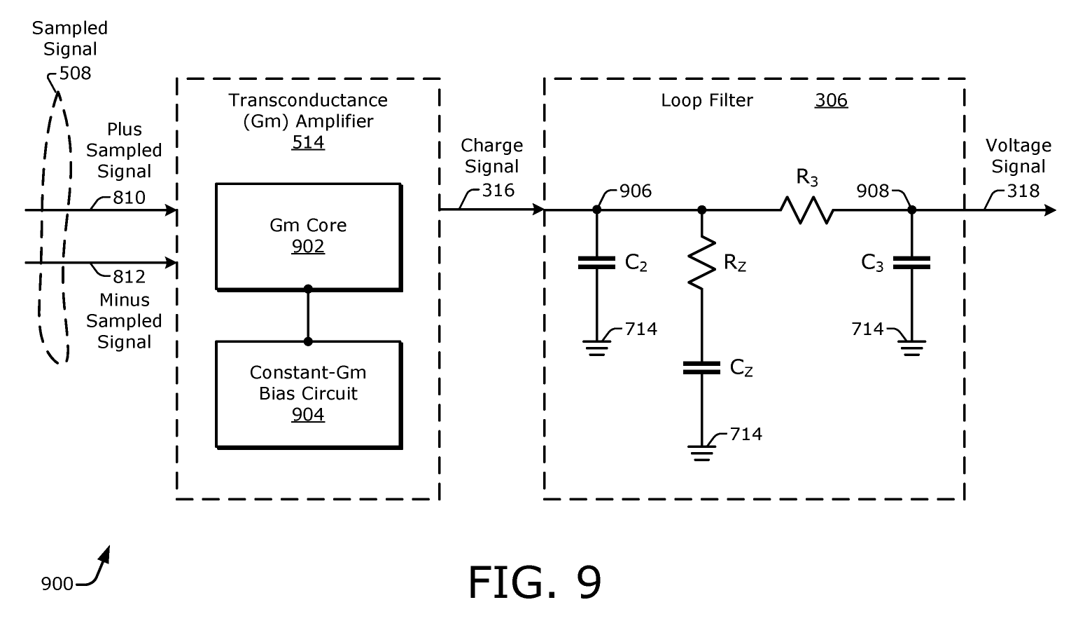

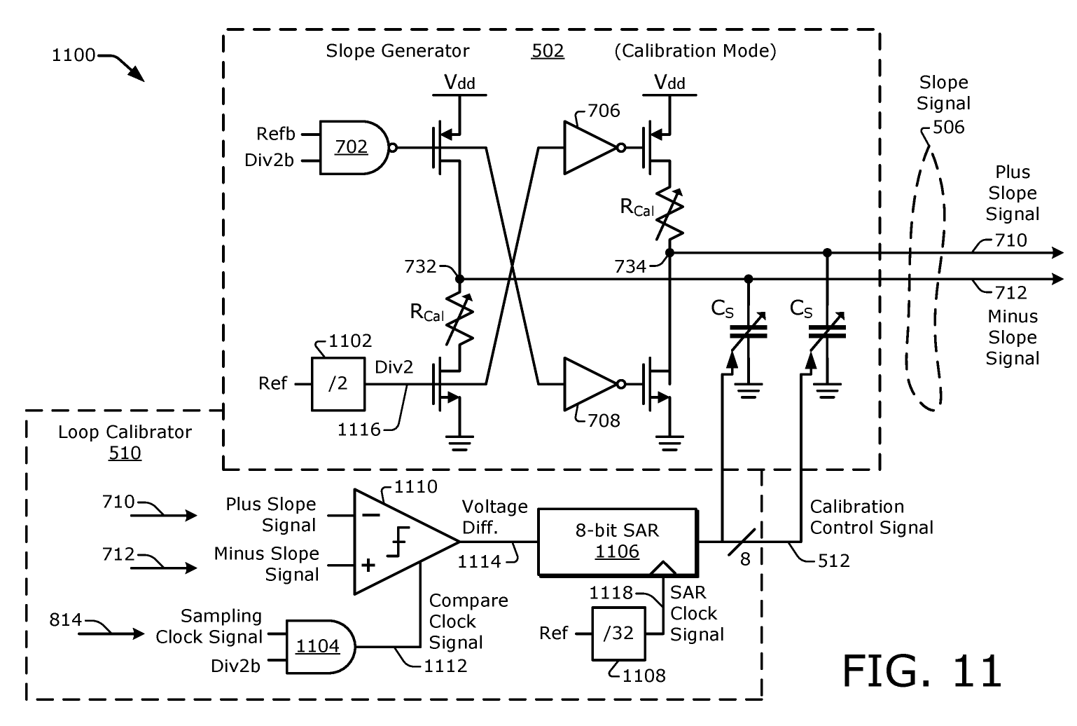

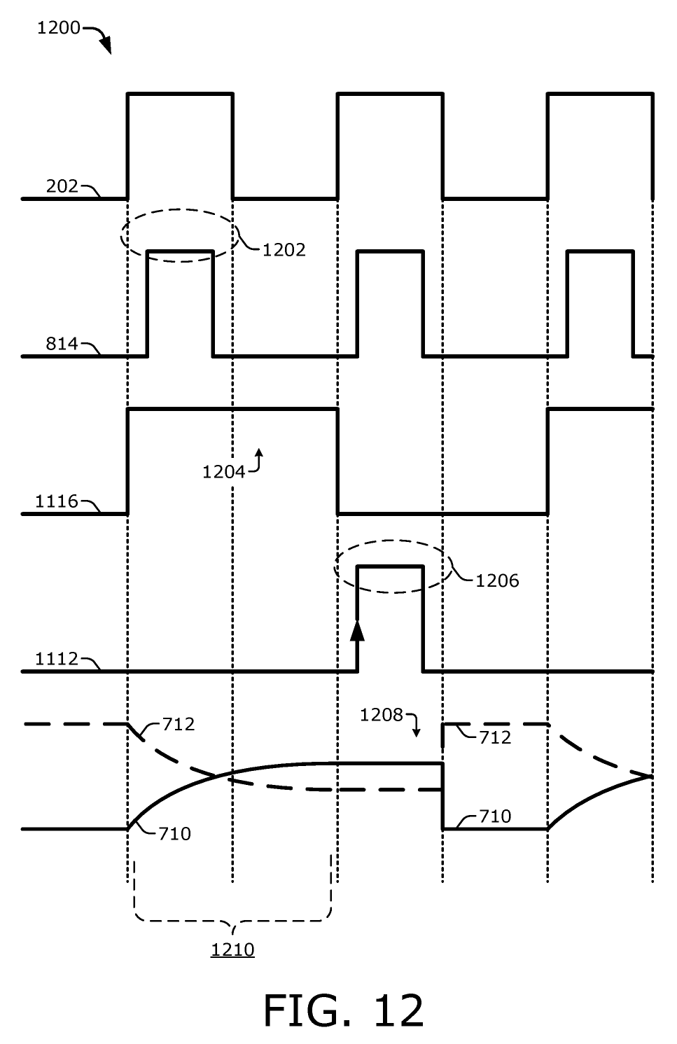

In the description below, example implementations of the sampling phase-locked loop 130 are described at a relatively higher level with reference to FIGS. 3-5. Example implementations of the phase frequency detector 302 are described at a relatively lower level with reference to FIG. 6. Example implementations of the relative phase signal determiner 322 are described at a relatively lower level with reference to FIGS. 7, 8, and 10-1 to 10-3. Example implementations of the amplifier 324 and the loop filter 306 are described at a relatively lower level with reference to FIG. 9. Further, additional example implementations pertaining to calibration of the relative phase signal determiner 322 are described with reference to FIGS. 11 and 12.

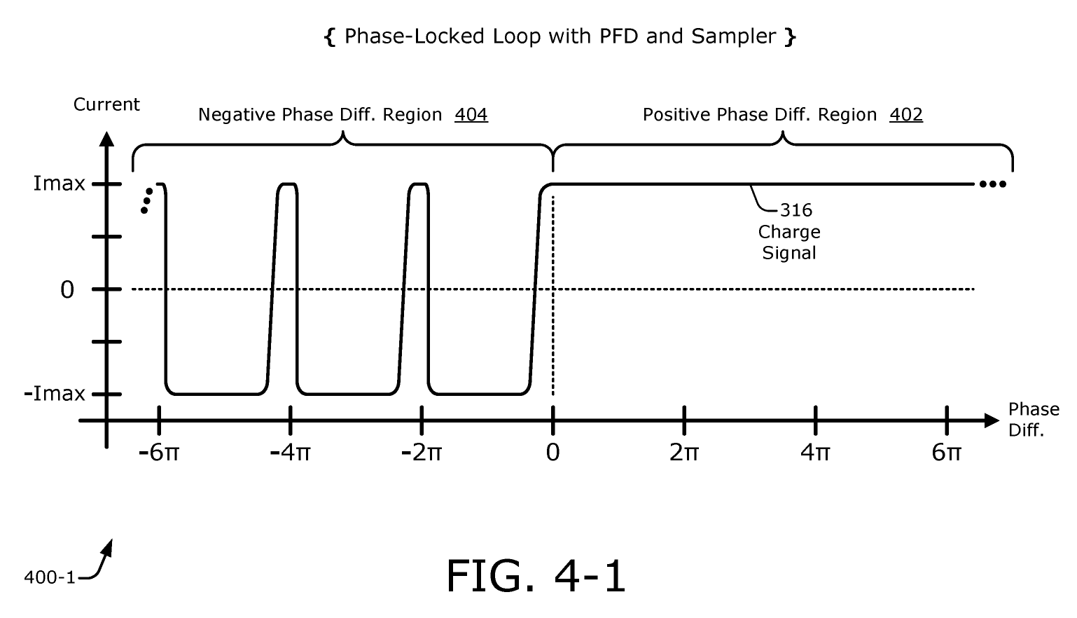

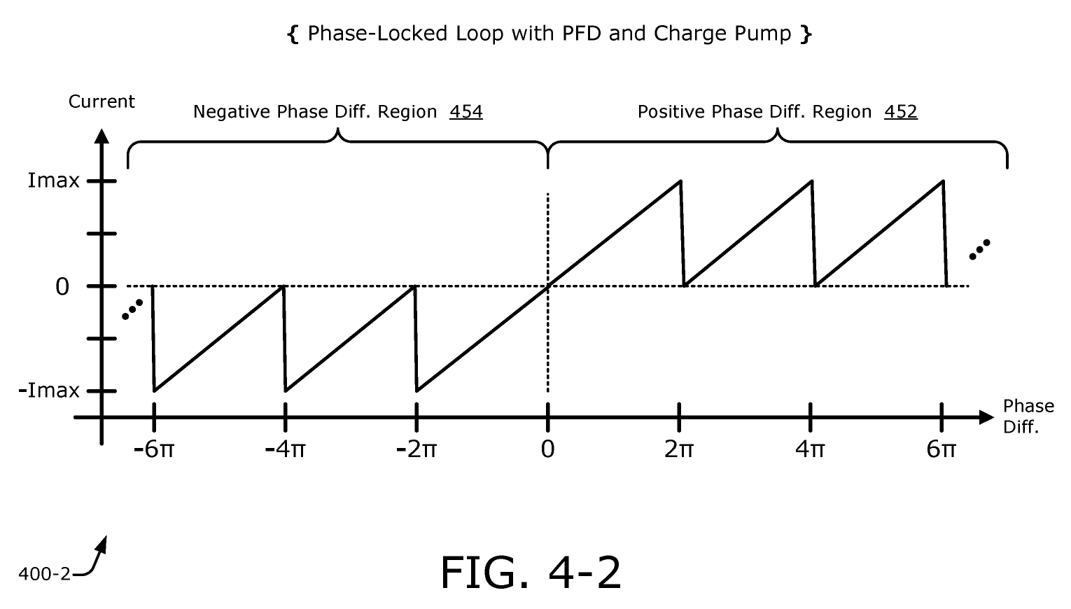

With phase-locked loops generally, settling time is an amount of time that elapses while a phase-locked loop locks to a multiple of a frequency of a reference signal. Shorter settling times enable circuitry to operate more quickly by reducing start-up latency. For the sampling phase-locked loop 130 of FIG. 3, settling time can be reduced by correctly indicating to the loop filter 306 with the charge signal 316 whether the voltage across the filter capacitor 308 should be increased or decreased at any given moment to bring the oscillating signal 204 into a locked state with the reference signal 202. Consequently, the speed of settling for the sampling phase-locked loop 130 is at least partially dependent on one or more attributes of the charge signal 316. FIG. 4-1 depicts example attributes of the charge signal 316 that are achievable using the sampling phase-locked loop 130 as described herein.

FIG. 4-1 illustrates a graph 400-1 of current versus phase difference that depicts an example occurrence of the charge signal 316 at an output of a charge signal generator 304 of a sampling phase-locked loop 130 (e.g., of FIG. 3). The phase difference is graphed along the horizontal or abscissa axis. The illustrated phase difference extends from −67c to 0 and from 0 to +6π, but the phase difference can extend farther in either or both directions. Here, the phase difference represents a difference between a phase of the reference signal 202 and a phase of the feedback signal 320. The current is graphed along the vertical or ordinate axis. The illustrated current extends from −Imax to 0 and from 0 to +Imax.

A traditional, non-sampling phase-locked loop includes a phase frequency detector and a charge pump. This non-sampling phase-locked loop exhibits a sawtooth-shaped charge signal that is provided to a loop filter. An example of such a sawtooth-shaped charge signal is depicted in FIG. 4-2. Thus, FIG. 4-2 illustrates a graph 400-2 of current versus phase difference for a phase-locked loop having a phase frequency detector (PFD) in conjunction with a charge pump. The graph 400-2 is separated into two regions: a negative phase difference region 454 and a positive phase difference region 452. As shown in the positive phase difference region 452, the current increases over some phase-difference range like a ramping signal, but then the current abruptly returns to zero with a very steep slope (e.g., at each multiple of “a”). With a positive phase difference, the traditional phase-locked loop provides a positive current. With a negative phase difference, the traditional phase-locked loop provides a negative current.

In contrast with non-sampling phase-locked loops, existing sampling-based phase-locked loops exhibit either a sine-shaped wave or a square-shaped wave for a current versus phase difference characteristic. Consequently, for a positive phase difference larger than a certain phase error, the output current is not positive. Similarly, for a negative phase difference larger than a certain phase error, the output current is not negative. Thus, the settling time of an existing sampling-based phase-locked loop can be significantly lengthened, to the extent that the settling time is even longer than that of a traditional, non-sampling phase-locked loop.

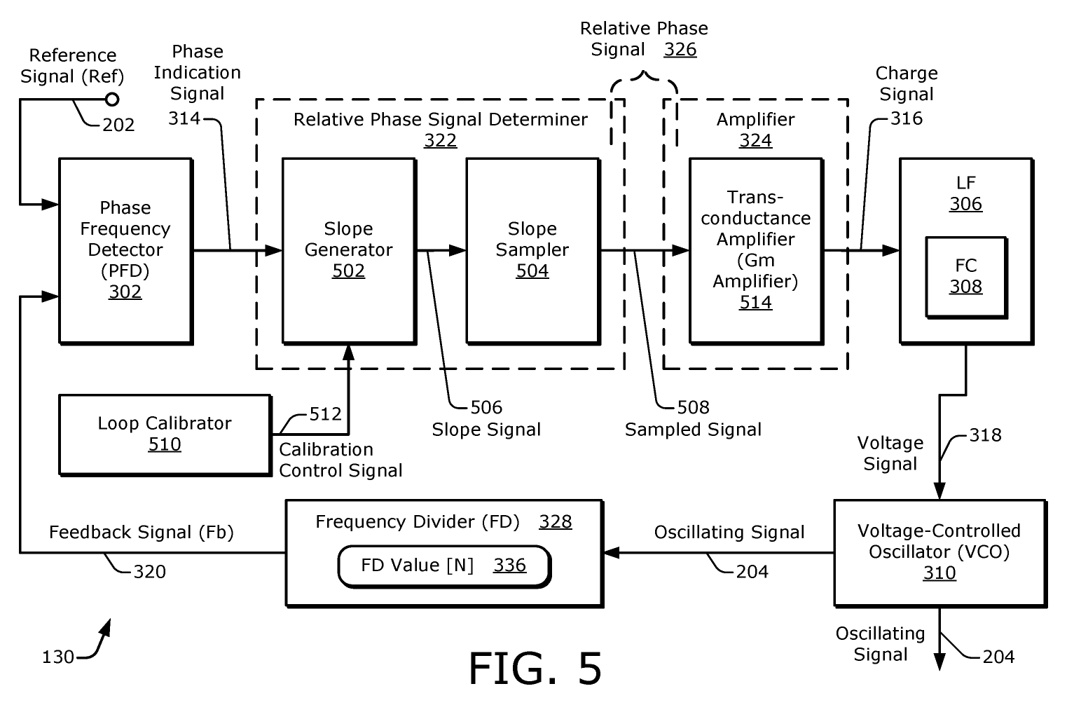

However, with a sampling phase-locked loop 130 as described herein, the charge signal 316 can remain positive as along as the phase difference is positive. With reference again to the graph 400-1 of FIG. 4-1, the example charge signal 316 provides a positive current as long as the phase difference is positive—e.g., as long as the reference signal 202 leads the feedback signal 320. Further, the example charge signal 316 provides a negative current for a negative phase difference. Note, however, that for a short period of time the current can be positive while the phase difference is negative, depending on a time constant of a slope generator (e.g., an RC time constant of a slope generator 502 (which is described below with reference to FIG. 5) of the relative phase signal determiner 322). This short period of time should not cause or result in cycle slipping, and the time period should have a relatively minor impact on settling time.

In some implementations, the charge signal generator 304 is configured to generate a charge signal 316 having the current profile depicted in FIG. 4-1. The graph 400-1 is separated into two regions: a negative phase difference region 404 and a positive phase difference region 402. As used herein, a positive phase difference corresponds to a situation in which the reference signal 202 leads the feedback signal 320, and a negative phase difference corresponds to a situation in which the reference signal 202 lags the feedback signal 320. However, the meaning of these two terms can be swapped by switching the polarities of the corresponding circuitries. As shown, the positive phase difference region 402 starts at zero and extends into the positive phase differences of +2π, +4π . . . . The negative phase difference region 404 starts at zero and extends into the negative phase differences of −2π, −4π . . . .

As described herein, the charge signal generator 304 can produce a different current profile in the positive phase difference region 402 as compared to in the negative phase difference region 404. In the positive phase difference region 402, the charge signal generator 304 produces the example charge signal 316 to exhibit a substantially-constant positive current throughout a range of positive phase differences. Thus, in this manner, the charge signal generator 304 can provide a mechanism for generating a charge signal 316 responsive to the phase indication signal 314, with the charge signal 316 including a substantially-constant positive current responsive to the phase indication signal 314 representing a positive phase difference. Analogously, the charge signal generator 304 can provide a mechanism for generating the charge signal 316 to include a primarily negative current responsive to the phase indication signal 314 representing a negative phase difference. Example circuitry that can implement the charge signal generator 304 so as to produce current levels like the current profile of the example charge signal 316 shown in FIG. 4-1 is described below, starting with FIG. 5 and including the signal timing diagrams of FIGS. 10-1 to 10-3.

FIG. 5 illustrates an example sampling phase-locked loop 130 that includes the relative phase signal determiner 322 and the amplifier 324 to implement the charge signal generator 304 of FIG. 3. Thus, the sampling phase-locked loop 130 of FIG. 5 is similar to that of FIG. 3. However, as shown in FIG. 5, the relative phase signal determiner 322 is realized with a slope generator 502 and a slope sampler 504. Further, the amplifier 324 is implemented as a transconductance amplifier 514 (Gm amplifier). The sampling phase-locked loop 130 can also employ a loop calibrator 510.

In example implementations, the phase frequency detector 302 is coupled to the slope generator 502, and the slope generator 502 is coupled to the slope sampler 504. The slope sampler 504 is coupled to the transconductance amplifier 514, which is coupled to the loop filter 306. The loop calibrator 510 is coupled to the relative phase signal determiner 322, such as the slope generator 502 thereof.

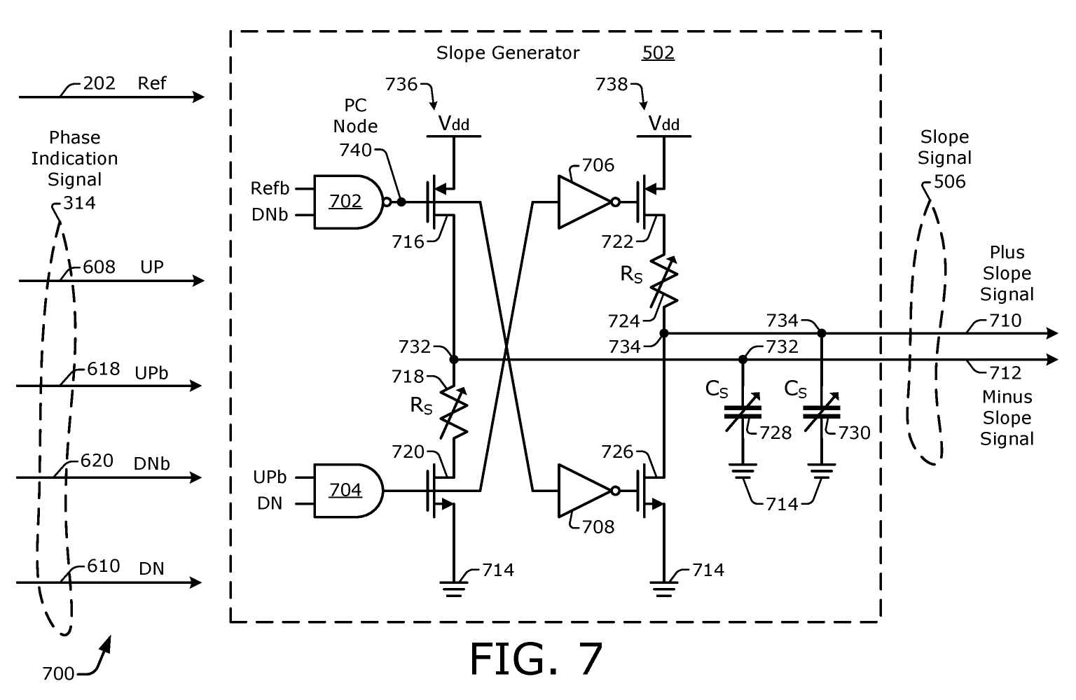

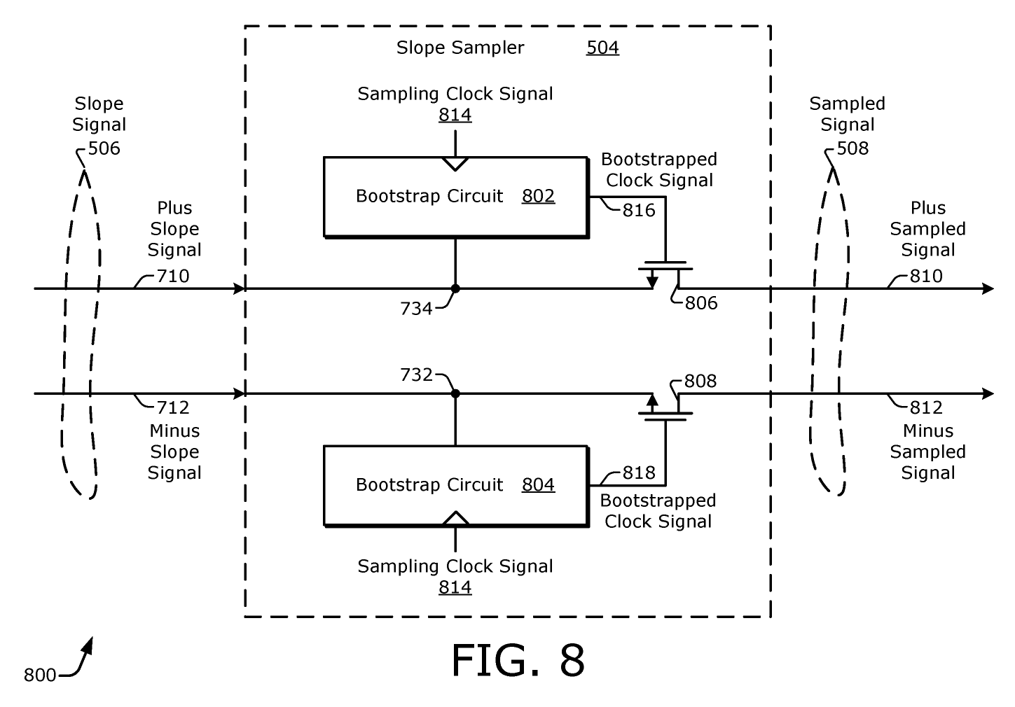

In example operations, the slope generator 502 generates a slope signal 506 based at least on the phase indication signal 314, which is received from the phase frequency detector 302. Example implementations of the slope generator 502 are described below with reference to FIG. 7. In these manners, the slope generator 502 can provide a mechanism for generating a slope signal 506 based on the phase indication signal 314. The slope sampler 504 receives the slope signal 506 from the slope generator 502. The slope sampler 504 samples the slope signal 506 to produce a sampled signal 508. Example implementations of the slope sampler 504 are described below with reference to FIG. 8. In these manners, the slope sampler 504 can provide a mechanism for sampling the slope signal 506 to produce a sampled signal 508, which signal comprises the relative phase signal 326. Example implementations of signaling across the relative phase signal determiner 322 are described below with reference to FIGS. 10-1 to 10-3.

The slope signal 506 and the sampled signal 508 can be implemented using differential signaling for input to the transconductance amplifier 514. The sampled signal 508 represents an example implementation of the relative phase signal 326. The transconductance amplifier 514 provides the charge signal 316 to the loop filter 306 based on the sampled signal 508. Example implementations of the transconductance amplifier 514 and the loop filter 306 are described below with reference to FIG. 9. The loop calibrator 510 provides a calibration control signal 512 to the slope generator 502 to establish a voltage change rate for the slope signal 506. Example implementations of the loop calibrator 510 are described below with reference to FIGS. 11 and 12.

FIG. 6 illustrates generally at 600 an example of circuitry for the phase frequency detector 302. As shown, the phase frequency detector 302 includes two “D” flip-flops, a flip-flop 602 and a flip-flop 604; and an AND gate 606. Each “D” flip-flop includes a “D” input, a “Q” output, a clocking input (“>”), and a reset terminal (R). The AND gate 606 includes a first input, a second input, and an output. The phase frequency detector 302 accepts as input the reference signal 202 and the feedback signal 320 and outputs the phase indication signal 314. The phase frequency detector 302, or related circuitry of the sampling phase-locked loop 130, can also include an inverter 612, an inverter 614, or one or more buffers (not shown) to provide the phase indication signal 314 to the slope generator 502 (e.g., of FIGS. 5 and 7). As indicated by the dashed-line loop on the right of FIG. 6, the phase indication signal 314 can include one or more of: an up signal 608 (UP), a down signal 610 (DN), an inverted up signal 618 (UPb), or an inverted down signal 620 (DNb).

The “D” input of the flip-flop 602 is coupled to a supply voltage (Vdd). The reference signal 202 is coupled to the clocking input of the flip-flop 602. The “Q” output of the flip-flop 602 produces the up signal 608 that is provided to the slope generator 502 as part of the phase indication signal 314. The up signal 608 is also coupled to the first input of the AND gate 606. The output of the AND gate 606 is coupled to the reset terminal (R) of the flip-flop 602. The “D” input of the flip-flop 604 is coupled to the supply voltage (Vdd). The feedback signal 320 is coupled to the clocking input of the flip-flop 604. The “Q” output of the flip-flop 604 produces the down signal 610 that is provided to the slope generator 502 as another part of the phase indication signal 314. The down signal 610 is coupled to the second input of the AND gate 606. The output of the AND gate 606 is also coupled to the reset terminal (R) of the flip-flop 604. As described next, the flip-flop 602 and the flip-flop 604 are configured to produce the up signal 608 and the down signal 610 responsive to a relative timing of an edge of the reference signal 202 and another edge of the feedback signal 320.

In operation, the two edge-triggered clocking inputs of the flip-flops 602 and 604 work in conjunction with the “D” inputs and the reset terminals (R) thereof using a feedback path (not separately indicated) that is internal to the phase frequency detector 302. This internal PFD feedback path includes the AND gate 606 and loops back to both of the flip-flops 602 and 604. When the reference signal 202 and the feedback signal 320 are both high, the previous rising edge of each of these two signals triggered the flip-flops 602 and 604, which caused both the up signal 608 and the down signal 610, respectively, to be high because the “D” inputs are tied high to the supply voltage (Vdd). This causes the AND gate 606 to output a high signal, which acts as a reset signal 622 that triggers the respective reset terminal (R) of each of the flip-flop 602 and the flip-flop 604. Thus, responsive to a high level of the reset signal 622 at the respective reset terminal (R), the flip-flop 602 changes the corresponding “Q” output to be low, and therefore causes the up signal 608 to have a low value.

Similarly, the flip-flop 604 changes the corresponding “Q” output to be low, and thus causes the down signal 610 to have a low value responsive to a high level of the reset signal 622 at the respective reset terminal (R) of the flip-flop 604. Next, whichever incoming signal—either the reference signal 202 or the feedback signal 320—goes high first, the signal at the corresponding “Q” output will likewise be driven high first. For instance, if the reference signal 202 goes high first, then the “Q” output of the flip-flop 602 goes high to drive the up signal 608 high. Conversely, if the feedback signal 320 goes high first, then the “Q” output of the flip-flop 604 goes high to drive the down signal 610 high. Thus, whichever output signal of the two flip-flops goes high first will remain high until the other incoming signal to the two flip-flops also goes high, thereby causing the AND gate 606 to trigger the reset terminals (R) via the reset signal 622.

Due to the interactions between the two flip-flops and the AND gate, the up signal 608 and the down signal 610 are jointly indicative of both the phase difference and the frequency difference between the reference signal 202 and the feedback signal 320 over time. While the phase frequency detector 302 is detecting both the phase difference and the frequency difference, the phase frequency detector 302 is also directly producing the up signal 608 and the down signal 610 to indicate either or both of these differences over time. Further, the inverter 612 and the inverter 614 are producing inverted versions of these up and down signals. Specifically, the inverter 612 receives the up signal 608, inverts a value thereof, and outputs the inverted up signal 618. Similarly, the inverter 614 receives the down signal 610, inverts a value thereof, and outputs the inverted down signal 620. Any portion or portions of the phase indication signal 314 can be forwarded to the slope generator 502 for further processing. Example implementations of how the slope generator 502 receives and processes the phase indication signal 314 to realize a sampling phase-locked loop 130 are described with reference to FIG. 7.

FIG. 7 illustrates generally at 700 an example of circuitry for the slope generator 502. As shown, the slope generator 502 receives as input one or more portions of the phase indication signal 314 and the reference signal 202. Based on these input signals, the slope generator 502 generates the slope signal 506. The slope generator 502 processes the input signals to produce the slope signal 506 to indicate whether the reference signal 202 leads or lags the feedback signal 320 at some particular moment. In some implementations, the slope signal 506 is realized using differential signaling, such as with a plus slope signal 710 and a minus slope signal 712.

As shown, the slope generator 502 includes multiple components arranged in two stacks that are coupled between the supply voltage (Vdd) and an equipotential node, such as ground 714. Each stack includes two transistors and one resistor, which can be adjustable. In some implementations, each transistor is implemented as a field effect transistor (FET), such as a p-channel FET (PFET) or an n-channel FET (NFET). Thus, each transistor includes a respective gate terminal, source terminal, and drain terminal.

A first stack of components 736 includes a transistor 716, a resistor 718 (Rs), and a transistor 720. The transistor 716, the resistor 718, and the transistor 720 are coupled together in series with the transistor 716 coupled to the supply voltage (Vdd) and the transistor 720 coupled to the ground 714. A second stack of components 738 includes a transistor 722, a resistor 724 (Rs), and a transistor 726. The transistor 722, the resistor 724, and the transistor 726 are coupled together in series with the transistor 722 coupled to the supply voltage (Vdd), and the transistor 726 coupled to the ground 714. As shown, the transistors that are coupled to the supply voltage (Vdd) can be implemented using a PFET, and the transistors that are coupled to the ground 714 can be implemented using an NFET. A respective source terminal of each of the transistor 716 and the transistor 722 is coupled to the supply voltage (Vdd). Analogously, a respective source terminal of each of the transistor 720 and the transistor 726 is coupled to the ground 714.

A node 734 is located between the resistor 724 and the transistor 726. A capacitor 730 (Cs), which may be adjustable, is coupled between the node 734 and the ground 714. A node 732 is located between the transistor 716 and the resistor 718. A capacitor 728 (Cs), which may be adjustable, is coupled between the node 732 and the ground 714. The slope generator 502 provides the plus slope signal 710 at the node 734 and the minus slope signal 712 at the node 732. The slope generator 502 produces these slope signal outputs based on multiple input signals, including on up and down signals 608, 610, 618, or 620 received from the phase frequency detector 302 and on the reference signal 202.

The slope generator 502 receives these input signals at gate terminals of the transistors via logic gates and processes the input signals using the first and second stacks of components 736 and 738. As illustrated, the logic gates include a NAND gate 702, an AND gate 704, an inverter 706, and an inverter 708. Generally, outputs of the NAND gate 702 and the AND gate 704 are provided to the transistors of the first stack of components 736, and inverted outputs of the NAND gate 702 and the AND gate 704 are provided via a cross-coupling routing to the transistors of the second stack of components 738. Specifically, an output of the NAND gate 702 is provided to a gate terminal of the transistor 716, and an inverted output of the NAND gate 702 is provided to a gate terminal of the transistor 726 via the inverter 708. Also, an output of the AND gate 704 is provided to a gate terminal of the transistor 720, and an inverted output of the AND gate 704 is provided to a gate terminal of the transistor 722 via the inverter 706.

In some implementations, the slope generator 502 accepts four different input signals, two at each of the NAND gate 702 and the AND gate 704. The NAND gate 702 receives at a first input thereof an inverted version of the reference signal 202—or inverted reference signal (Refb)—and at a second input thereof the inverted down signal 620 (DNb). The AND gate 704 receives at a first input thereof the inverted up signal 618 (UPb) and at a second input thereof the down signal 610 (DN). The outputs of the NAND gate 702 and the AND gate 704 cause the transistors to turn on or off (e.g., to act like a closed switch or like an open switch, respectively) to establish particular voltage levels at the node 732 and the node 734. These voltage levels change at a rate that is at least partially controlled by an interaction between the resistors Rs and the capacitors Cs. This rate of change for the voltages is described further with reference to the signal timing diagrams of FIGS. 10-1 to 10-3 and the RC calibration procedure performed by the loop calibrator 510 of FIGS. 11 and 12.

The slope generator 502 also implements pre-charging functionality. The transistor 716 and the transistor 726 each respectively comprise a pre-charge circuit to provide the pre-charging functionality. Each pre-charge circuit is configured to establish a “default” voltage level for the slope signal 506. The transistor 716 is coupled to the node 732 to establish an initial voltage level for the minus slope signal 712. The transistor 726 is coupled to the node 734 to establish an initial voltage level for the plus slope signal 710. These pre-charge circuits are coupled directly or indirectly to the pre-charge node 740 (PC Node) at the output of the NAND gate 702. Thus, each pre-charge circuit operates responsive to a voltage level at the pre-charge node 740.

In some implementations, the node 732 for the minus slope signal 712 is pre-charged to a high voltage level, such as by pulling a voltage thereof up to the supply voltage (Vdd). On the other hand, the node 734 for the plus slope signal 710 is pre-charged to a low voltage level, such as by pulling a voltage thereof down to the ground 714. These example initial voltage levels are depicted in the signal timing diagrams of FIGS. 10-1 to 10-3, as described below. To establish a high voltage level at the node 732, the transistor 716 is implemented as a pull-up transistor (e.g., a PFET) coupled between the supply voltage (Vdd) and the node 732. This pull-up transistor 716 is turned on if a pre-charge signal (PC) has a low voltage level, as provided from the pre-charge node 740 (PC Node).

To establish a low voltage level at the node 734, the transistor 726 is implemented as a pull-down transistor (e.g., an NFET) coupled between the node 734 and the ground 714. This pull-down transistor 726 is turned on if the pre-charge signal (PC) has a low voltage level because the pre-charge signal (PC) is inverted by the inverter 708 to produce a high voltage level at the gate terminal of the transistor 726. Thus, the voltage pre-charging is performed by the pre-charge circuits realized by the transistors 716 and 726 if both the inverted reference signal (Refb) and the inverted down signal 620 (DNb) have a high voltage level at the inputs to the NAND gate 702. The corresponding reference signal 202 and down signal 610 are explicitly shown in FIGS. 10-1 to 10-3. The timing signal diagrams in these figures indicate that the initial high voltage for the minus slope signal 712 and the initial low voltage for the plus slope signal 710 are established via pre-charging if the reference signal 202 and the down signal 610 are both low.

Thus, based on the input signals received at the NAND gate 702 and the AND gate 704, the slope generator 502 establishes voltage levels at the node 732 and the node 734. The pre-charge circuits realized by the transistors 716 and 726 establish initial voltage levels that can also be applied to, or permitted to continue in, a situation in which the reference signal 202 leads the feedback signal 320. However, as the relative phase difference between these two signals changes, the slope generator 502 changes the voltage levels at the node 732 and the node 734 in accordance with an RC time constant as described herein. These voltage levels are provided as the minus slope signal 712 and the plus slope signal 710, respectively. The minus slope signal 712 and the plus slope signal 710 are forwarded to the slope sampler 504 for sampling, as is described with reference to FIG. 8.

FIG. 8 illustrates generally at 800 an example of circuitry for the slope sampler 504. In example implementations, the slope sampler 504 receives the slope signal 506, samples the slope signal 506, and outputs the sampled signal 508 based on the sampling. Here, both the slope signal 506 and the sampled signal 508 are implemented with differential signaling. The sampled signal 508 therefore includes a plus sampled signal 810 and a minus sampled signal 812. Generally, the slope sampler 504 samples the plus slope signal 710 to produce the plus sampled signal 810 and samples the minus slope signal 712 to produce the minus sampled signal 812. As shown, the slope sampler 504 includes at least two bootstrap circuits and two transistors. The two transistors are implemented as FETs; however, each transistor may be implemented using a different transistor type, channel doping scheme, and so forth. Each transistor includes a source terminal, a drain terminal, and a gate terminal.

To maintain a low switch resistance for a range of input voltages, a bootstrap circuit and a transistor are utilized for the plus differential signal pathway, and another bootstrap circuit and another transistor are utilized for the minus differential signal pathway. With regard to the plus differential signal pathway in the top half of FIG. 8, a transistor 806 is coupled between the slope generator 502 (of FIGS. 5 and 7) and the transconductance amplifier 514 (of FIGS. 5 and 9). The transistor 806 is implemented as an NFET, but another transistor type may alternatively be used (e.g., a PFET). Here, a source terminal of the transistor 806 is coupled to the node 734. A drain terminal of the transistor 806 is coupled to the transconductance amplifier 514. A bootstrap circuit 802 is coupled between the node 734 and a gate terminal of the transistor 806.

In an example operation, the bootstrap circuit 802 controls when the transistor 806 samples the plus slope signal 710 responsive to the sampling clock signal 814. Responsive to a pulse or an edge of a pulse for the sampling clock signal 814, the bootstrap circuit 802 activates the bootstrapped clock signal 816. For instance, the bootstrap circuit 802 can drive the bootstrapped clock signal 816 high at the gate terminal of the transistor 806. Based on the bootstrapped clock signal 816, the transistor 806 secures the present value of the plus slope signal 710 as a value for the plus sampled signal 810. Thus, the transistor 806 samples the plus slope signal 710 to produce the plus sampled signal 810 responsive to the sampling clock signal 814 under the control of the bootstrap circuit 802.

Further, the bootstrap circuit 802 can keep Vgs (the voltage difference between the gate terminal and source terminal) of the transistor 806 approximately constant (e.g., within a given semiconductor process's capabilities) to maintain a substantially constant resistance across the transistor 806. For example, to keep the gate terminal voltage minus the source terminal voltage constant, even as the source voltage increases (or decreases), the bootstrap circuit 802 can increase (or decrease, respectively) the voltage at the gate terminal of the transistor 806. The bootstrap circuit 802 and the transistor 806 thus jointly operate to produce the plus sampled signal 810 by sampling the plus slope signal 710.

With regard to the minus differential signal pathway in the lower half of FIG. 8, a transistor 808 is coupled between the slope generator 502 and the transconductance amplifier 514. The transistor 808 is implemented here as an NFET, but another transistor type may alternatively be used. Here, a source terminal of the transistor 808 is coupled to the node 732. A drain terminal of the transistor 808 is coupled to the transconductance amplifier 514. A bootstrap circuit 804 is coupled between the node 732 and a gate terminal of the transistor 808. Thus, the circuitry for processing the minus differential signal is analogous to that of the plus differential signal. The operation of such circuitry is similarly analogous, as described below.

In an example operation, the bootstrap circuit 804 controls when the transistor 808 samples the minus slope signal 712 responsive to the sampling clock signal 814. Responsive to a pulse or an edge of a pulse for the sampling clock signal 814, the bootstrap circuit 804 activates a bootstrapped clock signal 818. Based on the bootstrapped clock signal 818, the transistor 808 secures the present value of the minus slope signal 712 as a value for the minus sampled signal 812. Thus, the transistor 808 samples the minus slope signal 712 to produce the minus sampled signal 812 responsive to the sampling clock signal 814 under the control of the bootstrap circuit 804. Further, the bootstrap circuit 804 can keep Vgs of the transistor 808 approximately constant to maintain a substantially constant resistance across the transistor 808. For example, to keep the gate terminal voltage minus the source terminal voltage substantially constant, even as the source voltage increases (or decreases), the bootstrap circuit 804 can increase (or decrease, respectively) the voltage at the gate terminal of the transistor 808. The bootstrap circuit 804 and the transistor 808 thus jointly operate to produce the minus sampled signal 812 by sampling the minus slope signal 712.

FIG. 9 illustrates example circuitry for the transconductance amplifier 514 (Gm amplifier) and example circuitry for the loop filter 306. The transconductance amplifier 514 receives the plus sampled signal 810 and the minus sampled signal 812 of the sampled signal 508. In operation, the transconductance amplifier 514 determines a voltage difference between the plus sampled signal 810 and the minus sampled signal 812, which both comprise voltage-based signals. For example, the transconductance amplifier 514 can subtract a voltage level of the plus sampled signal 810 from a voltage level of the minus sampled signal 812 to determine a voltage difference between the two voltage-based signals. The transconductance amplifier 514 amplifies this voltage differential and converts the voltage-based sampled signal 508 to a current-based signal to produce the charge signal 316.

In example implementations, the transconductance amplifier 514 includes a Gm core 902 and a constant-Gm bias circuit 904. The Gm core 902 is coupled to the constant-Gm bias circuit 904. The Gm core 902 can have a programmable Gm scaling factor. In operation, the Gm core 902 performs the transconductance amplification to produce the charge signal 316 based on the plus sampled signal 810 and the minus sampled signal 812. The constant-Gm bias circuit 904 operates to provide a constant Gm value across different PVT conditions.

Using a transconductance amplifier 514 as described herein can result in a number of features. First, with respect to implementing differential signaling, voltage supply noise in the slope generator is canceled out due to the differential sampling. Additionally, charge injection and clock feedthrough in the sampling switches (e.g., the transistors 806 and 808 of FIG. 8) appear as a common-mode at the differential inputs of the Gm amplifier. Thus, the effects of the charge injection and clock feedthrough are cancelled out at the output of the transconductance amplifier 514, which leads to low reference spurs.

Second, by using a Gm-cell, instead of an operational amplifier, issues related to a finite gain and gain bandwidth of an operational amplifier can be at least reduced. Third, with the constant-Gm bias circuit 904, the Gm can be designed to be proportional to 1/Rgm. The unity-gain frequency (coif) of the sampling phase-locked loop can be found as follows:

$${ω}_{u} \approx \frac{{T}_{ref}}{2 π} \frac{{V}_{DD}}{{R}_{s} {C}_{s}} {G}_{m} {R}_{z} \frac{{K}_{VCO}}{N} = \frac{{T}_{ref}}{2 π} \frac{{V}_{DD}}{{R}_{s} {C}_{s}} \frac{α}{{R}_{gm}} {R}_{z } \frac{{K}_{VCO}}{N} ,$$

where T_{ref} is the period of the reference signal 202, V_{DD} is the supply voltage of the slope generator 502, K_{vco} is the gain of the voltage-controlled oscillator 310 (VCO), N is the division ratio (frequency divider value 336) of the feedback frequency divider 328, and a is a constant. According to the above equation, by making the Gₘ be proportional to 1/Rgm and RsCs to be proportional to Tref, the bandwidth of the phase-locked loop can be maintained to be substantially constant over PVT variations. Thus, the Rgm resistance can be set to match the resistance of the resistor Rz of the loop filter 306, which is described below. In addition, the RsCs time constant for the slope generator 502 can be calibrated for minimum, or at least lower, phase-locked loop bandwidth variations over different process corners. Example approaches to such a calibration procedure are described below with reference to FIGS. 11 and 12.

In example implementations, the loop filter 306 receives the charge signal 316 in the form of a positive current or a negative current that increases or decreases a voltage across the filter capacitor 308 (e.g., of FIGS. 3 and 5). This voltage is provided by the loop filter 306 to the voltage-controlled oscillator 310 as the voltage signal 318. The filter capacitor 308 can include one or more capacitors, such as a capacitor C2, a capacitor C3, or a capacitor Cz, as illustrated. The loop filter 306 can also include at least one resistor, such as a resistor R3 or a resistor Rz.

As shown, the loop filter 306 includes an input node 906 and an output node 908. The capacitor C2 is coupled between the input node 906 and the ground 714. The resistor Rz and the capacitor Cz are coupled together in series between the input node 906 and the ground 714, with the capacitor Cz coupled between the resistor Rz and the ground 714. The resistor R3 is coupled between the input node 906 and the output node 908. The capacitor C3 is coupled between the output node 908 and the ground 714.

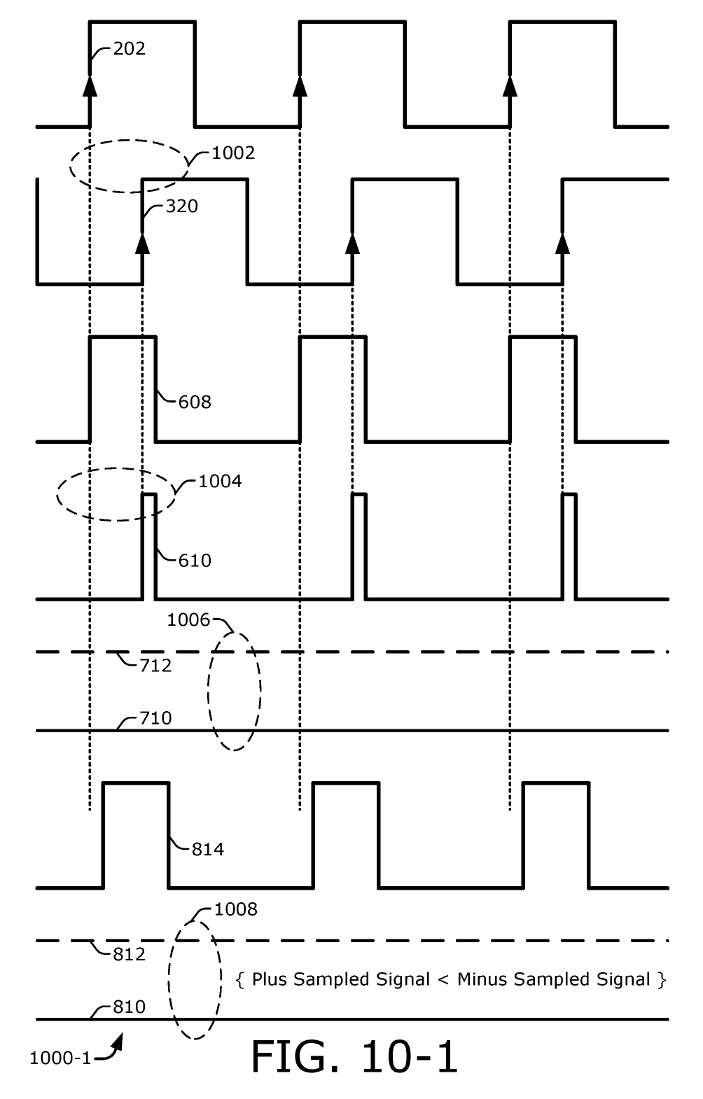

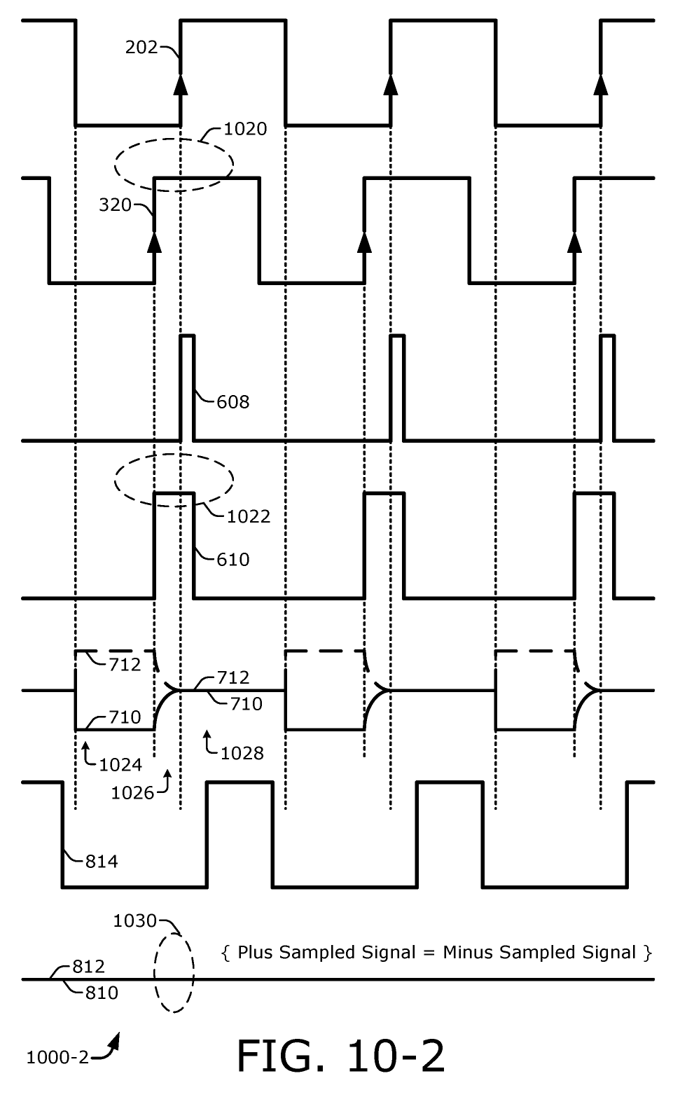

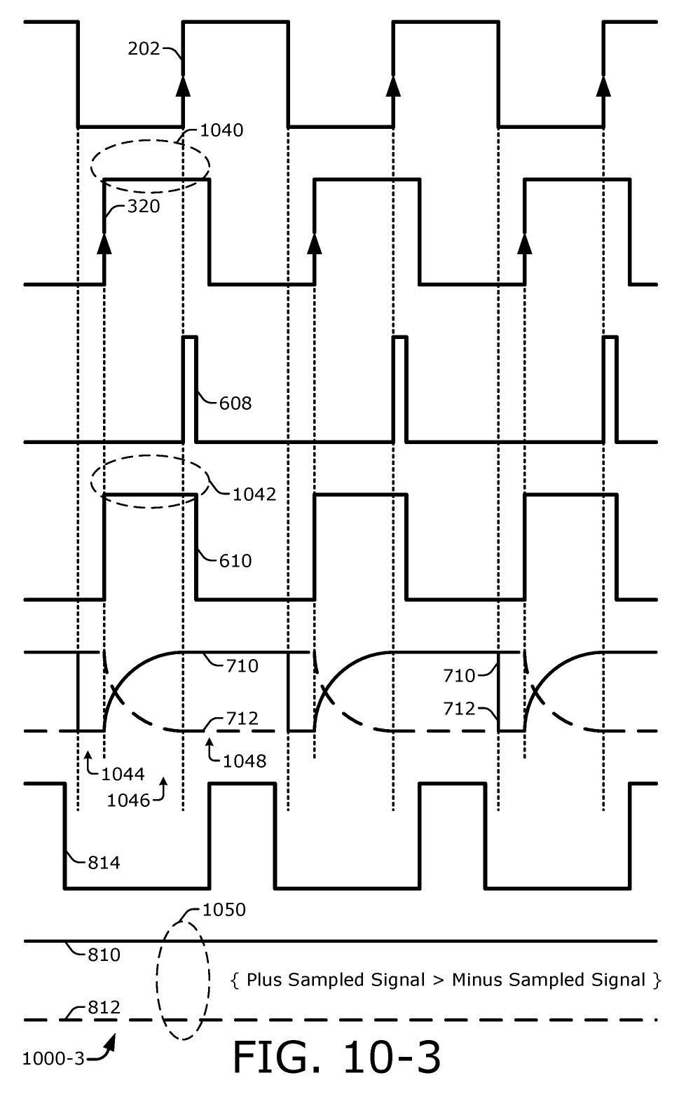

FIGS. 10-1 to 10-3 illustrate different signal timing diagrams for various situations during a locking operation. FIG. 10-1 corresponds to a situation in which the reference signal 202 leads the feedback signal 320 (e.g., a leading state). FIG. 10-2 corresponds to a situation in which the reference signal 202 is substantially locked to the feedback signal 320. FIG. 10-3 corresponds to a situation in which the reference signal 202 lags the feedback signal 320. Each signal timing diagram depicts the following signals, roughly from top to bottom: the reference signal 202, the feedback signal 320, the up signal 608, the down signal 610, the plus slope signal 710, the minus slope signal 712, the sampling clock signal 814, the plus sampled signal 810, and the minus sampled signal 812. In the drawings, the minus differential signals (e.g., the minus slope signal 712 and the minus sampled signal 812) are shown with dashed lines.

FIG. 10-1 illustrates an example signal timing diagram 1000-1 for a situation in which the reference signal 202 leads the feedback signal 320. As is apparent at 1002, the reference signal 202 leads the feedback signal 320 by some amount (e.g., period of time or phase). Accordingly, the up signal 608 goes high before the down signal 610, as indicated at 1004. Due to the operation of the phase frequency detector 302 (of FIG. 6), both the up signal 608 and the down signal 610 go low shortly after both become high due to the AND gate 606 and the reset terminals (R) of the flip-flops 602 and 604, as also indicated at 1004.

In example implementations, the slope generator 502 (of FIG. 7) processes the reference signal 202, the up signal 608, and the down signal 610 (including inverted versions of any given signal) to produce the plus slope signal 710 and the minus slope signal 712. Based on the values of the reference signal 202 and the down signal 610, the pre-charge circuits as implemented by the transistor 716 and the transistor 726 establish initial values at the nodes 732 and 734, respectively. Thus, the minus slope signal 712 is pulled up to a high voltage level by the transistor 716, and the plus slope signal 710 is pulled down to a low voltage level by the transistor 726, as indicated at 1006.

This initial pre-charging occurs based on the initial values that the phase frequency detector 302 inputs to the slope generator 502. The relevant values for the inputs to the slope generator 502, for sampling purposes, are determined at least partially by a time period just prior to, or at, a rising edge of the sampling clock signal 814. Based on these relevant values, the NAND gate 702 outputs a “1” (e.g., a high voltage). Based on this NAND gate output and that of the inverter 708, a high voltage is applied to the p-channel transistor 716, and a low voltage is applied to the n-channel transistor 726. Thus, the pull-up and pull-down pre-charging to Vdd and ground, respectively, is performed.

However, the outputs of the phase frequency detector 302, which are inputs to the slope generator 502, may change these initial pre-charge values in some situations during a given cycle. As described above, if both the reference signal 202 and the down signal 610 are low—as each is at the beginning of the cycle, the output of the NAND gate 702 becomes low. This low level at the pre-charge node 740 turns on both transistors 716 and 726, which makes the voltages at nodes 732 and 734 become Vdd and ground, respectively. On the other hand, the transistor 720 and the transistor 722 are off unless the output of the AND gate 704 goes high, which occurs if the down signal 610 is high and the up signal 608 is low. However, with reference to FIG. 10-1, this situation does not occur for the case in which the reference signal 202 leads the feedback signal 320. Consequently, the transistor 720 and the transistor 722 are both off for this case, and the plus slope signal 710 and the minus slope signal 712 remain at ground and Vdd, respectively. Similarly, the voltages of the plus sampled signal 810 and the minus sampled signal 812 are equal to ground and Vdd, respectively. This causes the transconductance amplifier 514 with the Gm core 902 to pump a current into the loop filter 306 steadily.

More specifically, the slope sampler 504 samples the minus slope signal 712 to secure a value for the minus sampled signal 812. The slope sampler 504 also samples the plus slope signal 710 to secure a value for the plus sampled signal 810. As indicated at 1008, the sampled value for the plus sampled signal 810 is less than the sampled value of the minus sampled signal 812. This voltage differential is applied to the transconductance amplifier 514 to increase the voltage at the loop filter 306 to thereby increase a frequency of the feedback signal 320 and therefore reduce the amount by which the reference signal 202 leads the feedback signal 320 (or, equivalently, reduce the amount by which the feedback signal 320 lags the reference signal 202).

FIG. 10-2 illustrates an example signal timing diagram 1000-2 for a situation in which the reference signal 202 is substantially phase-locked to the feedback signal 320 (e.g., a locking state). As indicated at 1020, the feedback signal 320 can nevertheless lead the reference signal 202 by up to some relatively small amount in terms of time or phase. This small amount is designed into the system to stabilize the locking process and to ensure that any positive phase difference between the reference signal 202 and the feedback signal 320 results in positive current to increase the frequency of the feedback signal 320. (See, e.g., the description of FIG. 4-1, especially for the positive phase difference region 402 and the area of the negative phase difference region 404 that is near zero phase.) Accordingly, the down signal 610 can go high as soon as slightly before the up signal 608 goes high, as indicated at 1022. Due to the operation of the phase frequency detector 302, both the up signal 608 and the down signal 610 go low shortly after both become high due to the AND gate 606 and the reset terminals (R) of the flip-flops 602 and 604.

In example implementations, the slope generator 502 (of FIG. 7) processes the reference signal 202, the up signal 608, and the down signal 610 (including inverted versions of any given signal) to produce the plus slope signal 710 and the minus slope signal 712. Due to the values of the reference signal 202 and the down signal 610, the pre-charge circuits realized by the transistor 716 and the transistor 726 initially drive the minus slope signal 712 high and the plus slope signal 710 low, as indicated at 1024. However, these initial pre-charged values can change as indicated at 1026.

At the time period for 1026, the down signal 610 goes high while the up signal 608 is still low. Based on the values of the signals input to the slope generator 502 at this time, the NAND gate 702 outputs a “1” (e.g., a high voltage), and the AND gate 704 outputs a “1” (e.g., a low voltage). A high voltage is applied to the p-channel transistor 716, and a high voltage is also applied to the n-channel transistor 720. Thus, current can flow through the lower half of the first stack of components 736, including through the resistor 718.

The outputs from the NAND gate 702 and the AND gate 704 are inverted by the inverter 708 and the inverter 706, respectively. A low voltage is therefore applied to the p-channel transistor 722, and a low voltage is also applied to the n-channel transistor 726. Thus, current can flow through the upper half of the second stack of components 738, including the resistor 724. With the transistors turned on or off in this manner, current can flow from the capacitor 728 through the resistor 718 to ground, thereby lowering the voltage at the node 732. In an analogous manner, current can flow from the source voltage (Vdd) through the resistor 724 to the capacitor 730, thereby increasing the voltage at the node 734. Consequently, the initial pre-charge voltage values are changed in accordance with a voltage change rate established by RsCs of the resistors 718 or 724 and the capacitors 728 or 730, respectively.

As indicated at 1026, the voltage level of the minus slope signal 712 decreases exponentially, and the voltage level of the plus slope signal 710 increases exponentially. This voltage change occurs until an approximately equal intermediate voltage is reached or the up signal 608 goes high, as shown at the beginning of 1028. In other words, the slope generator 502 has some amount of time, depending at least partially on the period of the reference signal 202, to adjust the voltage level(s) of the plus slope signal 710 and the minus slope signal 712. As shown at 1026, the slope generator 502 starts to drive the voltage levels of the plus slope signal 710 and the minus slope signal 712 to the intermediate voltage level responsive to the down signal 610 going high while the up signal 608 is still low.

As a result of the voltage changes, the plus slope signal 710 and the minus slope signal 712 are approximately equal, as indicated at 1028, when the sampling clock signal 814 presents a rising edge. The slope sampler 504 samples the minus slope signal 712 to secure a value for the minus sampled signal 812. The slope sampler 504 also samples the plus slope signal 710 to secure a value for the plus sampled signal 810. As indicated at 1030, the sampled value for the plus sampled signal 810 is approximately equal to the sampled value of the minus sampled signal 812. This voltage differential (which is approximately zero) is applied to the differential inputs of the transconductance amplifier 514 to maintain a currently-in-effect voltage at the loop filter 306 to thereby maintain a frequency of the feedback signal 320. This is designed to occur because the feedback signal 320 is considered substantially locked to the feedback signal 320 in this situation.

FIG. 10-3 illustrates an example signal timing diagram 1000-3 for a situation in which the reference signal 202 lags the feedback signal 320, as indicated at 1040 (e.g., a lagging state). Operation of the slope generator 502 for this situation is similar to the situation described above for FIG. 10-2, except the greater lag time causes the plus slope signal 710 and the minus slope signal 712 to be driven further from their respective initial pre-charged voltage values. The pre-charged voltage values are shown at 1044. As shown, the plus slope signal 710 has a low voltage value, and the minus slope signal 712 has a high voltage value.

As indicated at 1042, the rising edge of the down signal 610 occurs further in advance of the rising edge of the up signal 608. This enables the voltage changes of the plus slope signal 710 and the minus slope signal 712 to be greater before the rising edge of the up signal 608 arrives, as indicated at 1046. As shown at 1048, the two signals can swap voltage levels if there is sufficient time or the voltage change rate is sufficiently fast, as per the RsCs time constant programmable setting. Thus, in this example for a reference-signal-lagging situation, the slope generator 502 causes the plus slope signal 710 to have a high voltage level and the minus slope signal 712 to have a low voltage level by the time a rising edge of the sampling clock signal 814 arrives at 1048.

With reference also to FIG. 8, the transistor 808 samples the minus slope signal 712 to secure a value for the minus sampled signal 812. The transistor 806 samples the plus slope signal 710 to secure a value for the plus sampled signal 810. As indicated at 1050, the sampled value for the plus sampled signal 810 is high, and the sampled value of the minus sampled signal 812 is low. Thus, the sampled value for the plus sampled signal 810 is greater than the sampled value of the minus sampled signal 812. This voltage differential is applied to the transconductance amplifier 514 to decrease the voltage at the loop filter 306 to decrease a frequency of the feedback signal 320 and therefore reduce the amount by which the reference signal 202 lags the feedback signal 320 (or, equivalently, reduce the amount by which the feedback signal 320 leads the reference signal 202).

FIG. 11 illustrates an example calibration mode 1100 in which a slope generator 502 is calibrated by a loop calibrator 510. Generally, a loop calibration procedure is used to adjust the capacitive values of the capacitors Cs to obtain an RC time constant proportional to one period of the reference signal 202 (Ref). The capacitive values are adjusted so that a voltage change of the voltages at the nodes 732 and 734 can occur within one cycle of the reference signal (Ref). However, other approaches to calibrating the slope generator 502 can be adopted. For example, the desired voltage-change window can be shortened or lengthened, or resistance values of the resistors Rcal can alternatively or additionally be adjusted, such as by implementing a 4-bit programmable resistor for each.

In example implementations, the slope generator 502 operates in the calibration mode similarly to how it operates in the regular phase-locking mode; however, there are some differences, including with the structure of the circuitry. First, the inputs are different, as described next. Second, the AND gate 704 is replaced with a divide-by-two circuit 1102. The reference signal (Ref) is provided to an input of the divide-by-two circuit 1102, which produces a halved reference signal 1116 (Div2). The inverted reference signal (Refb) and an inverted halved reference signal (Div2b) are applied as the two inputs to the NAND gate 702. Third, the regular-mode resistors Rs are replaced by switching in calibration-mode resistors Rcal. Fourth, the output of the slope generator 502, the slope signal 506, is also routed to the loop calibrator 510.

The loop calibrator 510 includes a comparator 1110, an AND gate 1104, a successive approximation register 1106 (SAR 1106), and a divide-by-32 circuit 1108. In this example, the two capacitors Cs have an 8-bit programmability, so the SAR 1106 comprises an 8-bit SAR to control the 8-bit capacitor bank. Starting from the left of the loop calibrator 510, the minus input of the comparator 1110 receives the plus slope signal 710, and the plus input of the comparator 1110 receives the minus slope signal 712. The AND gate 1104 has two inputs. A first input receives the sampling clock signal 814, and a second input receives the inverted halved reference signal (Div2b). An output of the AND gate 1104 provides a compare clock signal 1112, which is routed to the comparator 1110. An output of the comparator 1110 is provided to an input of the SAR 1106. An output of the SAR 1106 provides a calibration control signal 512 that can include eight bits and be routed to a control terminal of the capacitors Cs. The SAR 1106 also has a clocking input. An output of the divide-by-32 circuit 1108 is based on the reference signal (Ref) and clocks the SAR 1106 as SAR clock signal 1118.

In an example operation, the comparator 1110 determines a voltage difference 1114 between the minus slope signal 712 and the plus slope signal 710. The comparator 1110 can output the voltage difference 1114 (e.g., a “0” or a “1,” depending on which is higher) responsive to the compare clock signal 1112. The AND gate 1104 outputs a high value for the compare clock signal 1112 responsive to both the sampling clock signal 814 and the inverted halved reference signal (Div2b) being high. Responsive to a high value of the compare clock signal 1112, the comparator 1110 performs the voltage difference determination and provides the voltage difference 1114 to the SAR 1106.

The SAR 1106 receives the voltage difference 1114. Responsive to the SAR clock signal 1118, the SAR 1106 is configured to gradually set the bit lines that control the capacitance of the capacitors Cs via the calibration control signal 512. For example, the SAR 1106 can identify bit values from the most significant bit (MSB) to the least significant bit (LSB) as part of a calibration feedback loop until the desired RcalCs adjustable time constant is established based on a period of the reference signal 202. Example signaling for the calibration feedback procedure is described with reference to FIG. 12.

FIG. 12 illustrates an example signal timing diagram 1200 for a calibration mode 1100 that is implemented by the slope generator 502 and the loop calibrator 510. The signal timing diagram 1220 depicts, from top to bottom, the reference signal 202 (Ref), the sampling clock signal 814, the halved reference signal 1116 (Div2), the compare clock signal 1112, the plus slope signal 710, and the minus slope signal 712. The sampling clock signal 814 goes high for a subset of the time that the reference signal 202 (Ref) is high, as indicated at 1202. The halved reference signal 1116 (Div2) has twice the period of the reference signal 202 (Ref), as indicated at 1204. Consequently, based on the operation of the AND gate 1104, the compare clock signal 1112 goes high every other time that the sampling clock signal 814 goes high, as indicated at 1206.

Responsive to the compare clock signal 1112 being high, the comparator 1110 provides the voltage difference 1114 to the SAR 1106, which voltage difference 1114 is determined at 1208. The SAR 1106 adjusts the RC “time constant” so that the voltage levels of the plus slope signal 710 and the minus slope signal 712 can become approximately equal within one-half a period of the halved reference signal 1116 (Div2), or equivalently within one reference cycle, as indicated at 1210. Each bit of the SAR 1106 can be determined over 32 periods (T) of the reference signal 202. Thus, an example total calibration time is (8*the period of the SAR clock signal 1118) or (256*the period of the reference signal 202 (Tref)). After calibration of the RC time constant, Rcal*Cs=(Tref/ln2). The resulting bandwidth can be well controlled because it depends on a ratio of resistors, as given by the unity gain frequency (ωᵤ) equation below:

$${ω}_{u} = \frac{{V}_{dd} ln 2}{2 π} \frac{{R}_{cal}}{{R}_{s}} \frac{α {R}_{z}}{{R}_{gm}} \frac{{K}_{VCO}}{N} ,$$

where V_{dd} is the supply voltage, R_{cal} is the resistance during calibration mode, Rs is the resistance during a regular locking mode, a is a constant of the transconductance amplifier 514, R_{gm} is the resistance of the transconductance amplifier 514, K_{VCO} is a constant of the voltage-controlled oscillator 310, and N is the frequency divider value 336.

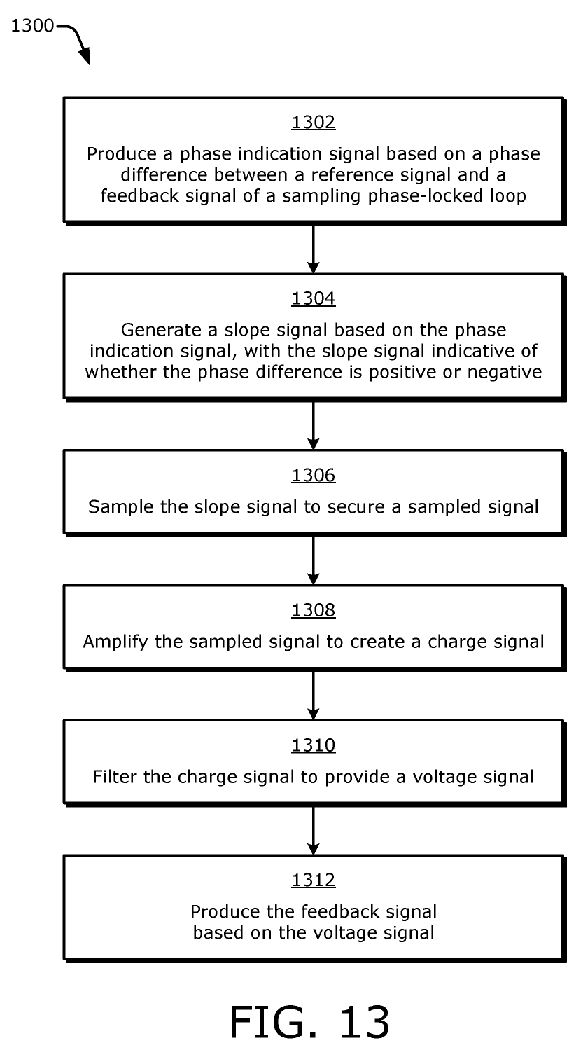

FIG. 13 is a flow diagram illustrating an example process 1300 for operating a sampling phase-locked loop. The process 1300 is described in the form of a set of blocks 1302-1312 that specify operations that can be performed. However, operations are not necessarily limited to the order shown in FIG. 13 or described herein, for the operations may be implemented in alternative orders or in fully or partially overlapping manners. Operations represented by the illustrated blocks of the process 1300 may be performed by a sampling phase-locked loop 130. More specifically, the operations of the process 1300 may be performed by the components illustrated in FIGS. 3 and 5 generally and in greater detail in FIGS. 6 through 10-3.

At block 1302, a phase indication signal is produced based on a phase difference between a reference signal and a feedback signal of the sampling phase-locked loop. For example, a phase frequency detector 302 can produce a phase indication signal 314 based on a phase difference between a reference signal 202 and a feedback signal 320 of the sampling phase-locked loop 130. The phase frequency detector 302 may produce, for instance, an up signal 608 and a down signal 610 using two “D” flip-flops.

At block 1304, a slope signal is generated based on the phase indication signal, with the slope signal indicative of whether the phase difference is positive or negative. For example, a slope generator 502 can generate a slope signal 506 based on the phase indication signal 314, with the slope signal 506 indicative of whether the phase difference is positive or negative. In operation, the slope generator 502 may generate a plus slope signal 710 and a minus slope signal 712 that jointly indicate a relative phase difference between the reference signal 202 and the feedback signal 320 using at least the up signal 608 and the down signal 610, including an inverted version thereof.

At block 1306, the slope signal is sampled to secure a sampled signal. For example, a slope sampler 504 can sample the slope signal 506 to secure a sampled signal 508. The sampling may be performed by at least one switch. For instance, a transistor 806 may secure a plus voltage level of the plus slope signal 710 for a plus sampled signal 810, and a transistor 808 may secure a minus voltage level of the minus slope signal 712 for a minus sampled signal 812.

At block 1308, the sampled signal is amplified to create a charge signal. For example, an amplifier 324 can amplify the sampled signal 508 to create a charge signal 316. In some differential-signaling-based implementations, a transconductance amplifier 514 may amplify a voltage difference between the plus voltage level of the plus sampled signal 810 and a minus voltage level of the minus sampled signal 812 and output a current-based charge signal 316 responsive to the voltage difference.

At block 1310, the charge signal is filtered to provide a voltage signal. For example, a loop filter 306 can filter the charge signal 316 to provide a voltage signal 318. To do so, a voltage across a filter capacitor 308 of the loop filter 306 may be increased or decreased based on whether the charge signal 316 sources or sinks current, with the voltage across the filter capacitor 308 providing the voltage signal 318.

At block 1312, the feedback signal is produced based on the voltage signal. For example, a feedback path 312 can produce the feedback signal 320 based on the voltage signal 318. To do so, a frequency divider 328 of the feedback path 312 may divide an oscillating signal 204, which is produced by a voltage-controlled oscillator 310 based on the voltage signal 318, by some frequency divider value 336.

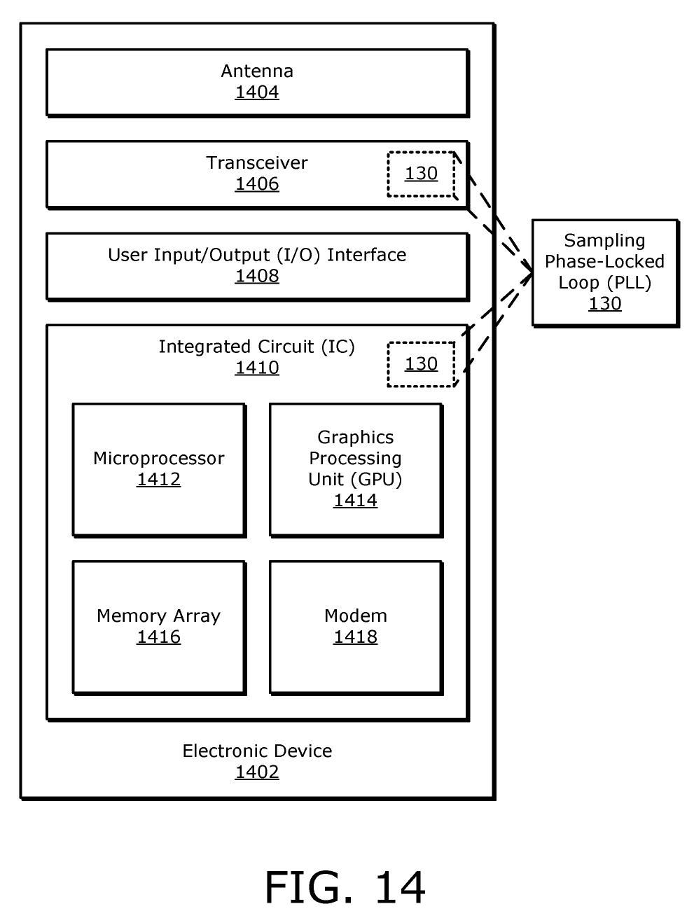

FIG. 14 illustrates an example electronic device 1402 that includes an integrated circuit 1410 (IC) having multiple cores. As shown, the electronic device 1402 includes an antenna 1404, a transceiver 1406, and a user input/output (I/O) interface 1408, in addition to the integrated circuit 1410. Illustrated examples of the integrated circuit 1410, or cores thereof, include a microprocessor 1412, a graphics processing unit (GPU) 1414, a memory array 1416, and a modem 1418. In one or more example implementations, a sampling phase-locked loop 130 as described herein can be implemented by the transceiver 1406, by the integrated circuit 1410, and so forth so that a signal having a desired frequency can be synthesized with less phase noise.

The electronic device 1402 can be a mobile or battery-powered device or a fixed device that is designed to be powered by an electrical grid. Examples of the electronic device 1402 include a server computer, a network switch or router, a blade of a data center, a personal computer, a desktop computer, a notebook or laptop computer, a tablet computer, a smart phone, an entertainment appliance, or a wearable computing device such as a smartwatch, intelligent glasses, or an article of clothing. An electronic device 1402 can also be a device, or a portion thereof, having embedded electronics. Examples of the electronic device 1402 with embedded electronics include a passenger vehicle, industrial equipment, a refrigerator or other home appliance, a drone or other unmanned aerial vehicle (UAV), or a power tool.

For an electronic device with a wireless capability, the electronic device 1402 includes an antenna 1404 that is coupled to a transceiver 1406 to enable reception or transmission of one or more wireless signals. The integrated circuit 1410 may be coupled to the transceiver 1406 to enable the integrated circuit 1410 to have access to received wireless signals or to provide wireless signals for transmission via the antenna 1404. The electronic device 1402 as shown also includes at least one user I/O interface 1408. Examples of the user I/O interface 1408 include a keyboard, a mouse, a microphone, a touch-sensitive screen, a camera, an accelerometer, a haptic mechanism, a speaker, a display screen, or a projector. The transceiver 1406 can correspond to, for example, the wireless transceiver 120 (e.g., of FIGS. 1 and 2) that implements a sampling phase-locked loop 130 as described herein.

The integrated circuit 1410 may comprise, for example, one or more instances of a microprocessor 1412, a GPU 1414, a memory array 1416, a modem 1418, and so forth. The microprocessor 1412 may function as a central processing unit (CPU) or other general-purpose processor. Some microprocessors include different parts, such as multiple processing cores, that may be individually powered on or off. The GPU 1414 may be especially adapted to process visual-related data for display, such as video data images. If visual-related data is not being rendered or otherwise processed, the GPU 1414 may be fully or partially powered down. The memory array 1416 stores data for the microprocessor 1412 or the GPU 1414. Example types of memory for the memory array 1416 include random access memory (RANI), such as dynamic RANI (DRAM) or static RANI (SRAM); flash memory; and so forth. If programs are not accessing data stored in memory, the memory array 1416 may be powered down overall or block-by-block. The modem 1418 demodulates a signal to extract encoded information or modulates a signal to encode information into the signal. If there is no information to decode from an inbound communication or to encode for an outbound communication, the modem 1418 may be idled to reduce power consumption. The integrated circuit 1410 may include additional or alternative parts than those that are shown, such as an I/O interface, a sensor such as an accelerometer, a transceiver or another part of a receiver chain, a customized or hard-coded processor such as an application-specific integrated circuit (ASIC), and so forth.

The integrated circuit 1410 may also comprise a system-on-chip (SoC). An SoC may integrate a sufficient number of different types of components to enable the SoC to provide computational functionality as a notebook computer, a mobile phone, or another electronic apparatus using one chip, at least primarily. Components of an SoC, or an integrated circuit 1410 generally, may be termed cores or circuit blocks. Examples of cores or circuit blocks include, in addition to those that are illustrated in FIG. 14, a voltage regulator, a main memory or cache memory block, a memory controller, a general-purpose processor, a cryptographic processor, a video or image processor, a vector processor, a radio, an interface or communications subsystem, a wireless controller, or a display controller. Any of these cores or circuit blocks, such as a central processing unit or a multimedia processor, may further include multiple internal cores or circuit blocks.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Further, items represented in the accompanying figures and terms discussed herein may be indicative of one or more items or terms, and thus reference may be made interchangeably to single or plural forms of the items and terms in this written description. Finally, although subject matter has been described in language specific to structural features or methodological operations, it is to be understood that the subject matter defined in the appended claims is not necessarily limited to the specific features or operations described above, including not necessarily being limited to the organizations in which features are arranged or the orders in which operations are performed.

1. An apparatus comprising:
a phase frequency detector configured to produce a phase indication signal based on a reference signal and a feedback signal;
a slope generator coupled to the phase frequency detector and configured to generate a slope signal based on the phase indication signal, the slope signal indicative of whether the reference signal leads or lags the feedback signal;
a slope sampler coupled to the slope generator and including at least one switch, the slope sampler configured to secure a sampled signal representative of a present value of the slope signal using the at least one switch and responsive to at least one clock signal, the slope sampler further configured to cause the sampled signal to cease representing the present value of the slope signal using the at least one switch and responsive to the at least one clock signal;
a voltage-controlled oscillator coupled to the slope sampler and configured to produce an oscillating signal based on the sampled signal; and
a feedback path disposed between the voltage-controlled oscillator and the phase frequency detector, the feedback path configured to provide the feedback signal to the phase frequency detector using the oscillating signal.

2. The apparatus of claim 1, further comprising:
a phase-locked loop that defines a feedback loop including the phase frequency detector, the slope generator, the slope sampler, the voltage-controlled oscillator, and the feedback path, wherein
the phase frequency detector, the slope generator, the slope sampler, and the voltage-controlled oscillator are coupled together in series along the feedback loop; and
the phase-locked loop is configured to establish a signal flow around the feedback loop, at least a portion of the signal flow propagating from the phase frequency detector, through both the slope generator and the slope sampler, and to the voltage-controlled oscillator.

3. The apparatus of claim 1, wherein:
the slope generator is configured to generate the slope signal based on the phase indication signal and the reference signal; and
the at least one switch comprises at least one transistor.

4. The apparatus of claim 1, wherein:
the phase indication signal comprises an up signal and a down signal;
the slope signal comprises a plus slope signal and a minus slope signal; and
the slope generator is configured to process the up signal and the down signal to generate the plus slope signal and the minus slope signal to have respective voltage levels that are jointly indicative of whether the reference signal leads or lags the feedback signal.

5. The apparatus of claim 1, further comprising:
an amplifier coupled to the slope sampler and configured to create a charge signal based on the sampled signal; and
a loop filter coupled to the amplifier and configured to provide a voltage signal based on the charge signal,
wherein the voltage-controlled oscillator is coupled to the loop filter and configured to produce the oscillating signal based on the voltage signal.

6. An electronic device comprising:
a phase frequency detector configured to produce a phase indication signal based on a phase difference between a reference signal and a feedback signal;
current means for generating a charge signal responsive to the phase indication signal, the charge signal including a substantially constant positive current responsive to the phase indication signal representing a positive phase difference, the current means coupled to the phase frequency detector and comprising:
generation means for generating a slope signal based on the phase indication signal, the slope signal indicative of whether the reference signal leads or lags the feedback signal; and
sampling means for sampling the slope signal responsive to at least one clock signal using at least one switch to produce a sampled signal for the charge signal, the sampled signal representative of a present value of the slope signal, the sampling means configured to cause the sampled signal to cease representing the present value of the slope signal using the at least one switch and responsive to the at least one clock signal;
a voltage-controlled oscillator coupled to the current means and configured to produce an oscillating signal based on the charge signal; and
a feedback path disposed between the voltage-controlled oscillator and the phase frequency detector, the feedback path configured to provide the feedback signal to the phase frequency detector using the oscillating signal.

7. The electronic device of claim 6, wherein the current means comprises means for generating the charge signal to include a primarily negative current responsive to the phase indication signal representing a negative phase difference.

8. (canceled)

9. The electronic device of claim 6, wherein the current means further comprises:
amplification means for amplifying the sampled signal to produce the charge signal.

10. (canceled)

11. (canceled)

12. A method for operating a sampling phase locked loop (PLL), the method comprising:
producing a phase indication signal based on a phase difference between a reference signal and a feedback signal of the sampling phase locked loop;
generating a slope signal based on the phase indication signal, the slope signal indicative of whether the phase difference is positive or negative;
sampling the slope signal to secure a sampled signal using at least one switch;
amplifying the sampled signal to create a charge signal;
filtering the charge signal to provide a voltage signal;
producing an oscillating signal based on the voltage signal; and
producing the feedback signal based on the oscillating signal.

13. The method of claim 12, wherein the producing the phase indication signal comprises:
detecting the phase difference between the reference signal and the feedback signal; and
detecting a frequency difference between the reference signal and the feedback signal.

14. The method of claim 13, wherein the phase indication signal comprises an up signal and a down signal, the up signal and the down signal jointly indicative of the phase difference and the frequency difference over time.

15. The method of claim 12, wherein the generating comprises generating the slope signal responsive to a voltage change rate, the voltage change rate based on a resistor and a capacitor.

16. The method of claim 15, further comprising:
calibrating a value for at least one of the resistor or the capacitor based on a frequency of the reference signal.

17. The method of claim 12, further comprising:
implementing differential signaling for the slope signal and the sampled signal.

18. The method of claim 12, wherein:
the at least one switch comprises a first switch and a second switch;
the slope signal comprises a plus slope signal and a minus slope signal;
the sampled signal comprises a plus sampled signal and a minus sampled signal; and
the sampling comprises:
sampling the plus slope signal to secure the plus sampled signal using the first switch responsive to a sampling clock signal; and
sampling the minus slope signal to secure the minus sampled signal using the second switch responsive to the sampling clock signal.

19. The method of claim 18, wherein:
the charge signal comprises a current-based signal;
the plus sampled signal and the minus sampled signal comprise voltage-based signals; and
the amplifying comprises:
determining a voltage difference between a plus voltage level of the plus sampled signal and a minus voltage level of the minus sampled signal; and
outputting a current as the charge signal based on the voltage difference.

20. The method of claim 12, wherein:
the producing the oscillating signal comprises controlling a frequency of the oscillating signal responsive to the voltage signal; and
the producing the feedback signal comprises providing the feedback signal based on the oscillating signal and a frequency divider value.

21. An apparatus comprising:
a sampling phase-locked loop (PLL) comprising:
a phase frequency detector configured to produce a phase indication signal based on a reference signal and a feedback signal;
a slope generator coupled to the phase frequency detector and configured to generate a slope signal based on the phase indication signal;
a slope sampler coupled to the slope generator and including at least one switch, the slope sampler configured to secure a sampled signal from the slope signal using the at least one switch;
a transconductance amplifier coupled to the slope sampler and configured to create a charge signal based on the sampled signal;
a loop filter coupled to the transconductance amplifier and configured to provide a voltage signal based on the charge signal;
a voltage-controlled oscillator coupled to the loop filter and configured to produce an oscillating signal based on the voltage signal; and
a feedback path disposed between the voltage-controlled oscillator and the phase frequency detector, the feedback path configured to provide the feedback signal to the phase frequency detector using the oscillating signal.

22. The apparatus of claim 21, wherein:
the phase indication signal comprises an up signal and a down signal;
the phase frequency detector includes a flip flop that is configured to be triggered responsive to an edge of the reference signal;
the phase frequency detector includes another flip flop that is configured to be triggered responsive to another edge of the feedback signal; and
the flip flop and the other flip flop are configured to produce the up signal and the down signal responsive to a relative timing of the edge of the reference signal and the other edge of the feedback signal.

23. The apparatus of claim 21, wherein:
the slope signal is indicative at least of whether the reference signal leads or lags the feedback signal; and
the slope signal comprises a plus slope signal and a minus slope signal.

24. The apparatus of claim 23, wherein:
the slope generator is configured to establish a plus voltage level of the plus slope signal and a minus voltage level of the minus slope signal relative to each other to indicate a leading state, a lagging state, or a locked state with respect to the reference signal and the feedback signal.

25. The apparatus of claim 24, wherein:
the slope generator comprises:
a first stack of components including two transistors and a resistor;
a capacitor coupled to the first stack of components at a node;
a second stack of components including two other transistors and another resistor; and
another capacitor coupled to the second stack of components at another node;
the slope generator is configured to generate the plus voltage level of the plus slope signal at the node; and
the slope generator is configured to generate the minus voltage level of the minus slope signal at the other node.

26. The apparatus of claim 23, wherein:
the at least one switch comprises a first switch and a second switch;
the sampled signal comprises a plus sampled signal and a minus sampled signal;
the slope sampler is configured to secure the plus sampled signal from the plus slope signal using the first switch; and
the slope sampler is configured to secure the minus sampled signal from the minus slope signal using the second switch.

27. The apparatus of claim 26, wherein:
the first switch comprises a transistor;
the transistor is coupled to the slope generator and configured to receive the plus slope signal, the transistor configured to secure the plus sampled signal from the plus slope signal responsive to a bootstrapped clock signal; and
the slope sampler comprises a bootstrap circuit coupled to the transistor and configured to produce the bootstrapped clock signal to bias the transistor responsive to changing voltage levels of the plus slope signal.

28. The apparatus of claim 26, wherein:
the charge signal comprises a current-based signal;
the loop filter includes a capacitor that is configured to receive the current-based signal; and
the transconductance amplifier is configured to amplify a voltage difference between a plus voltage level of the plus sampled signal and a minus voltage level of the minus sampled signal to create the current-based signal.

29. The apparatus of claim 21, wherein:
the feedback path comprises a frequency divider coupled to the voltage-controlled oscillator and the phase frequency detector; and
the frequency divider is configured to provide the feedback signal to the phase frequency detector by applying a frequency divider value to the oscillating signal.

30. The apparatus of claim 21, wherein the sampling phase-locked loop (PLL) further comprises:
a loop calibrator coupled to the slope generator, the loop calibrator configured to adjust a voltage change rate of the slope generator based on a frequency of the reference signal and responsive to the slope signal during a calibration mode of the sampling phase-locked loop.

31. The apparatus of claim 1, further comprising:
an antenna; and
a wireless transceiver coupled to the antenna, wherein
the phase frequency detector, the slope generator, the slope sampler, the voltage-controlled oscillator, and the feedback path comprise at least part of a sampling phase-locked loop (PLL); and
the wireless transceiver includes the sampling phase-locked loop and is configured to process wireless signals communicated via the antenna using the sampling phase-locked loop.

32. The apparatus of claim 31, further comprising:
a display screen; and
a processor operably coupled to the display screen and the wireless transceiver, the processor configured to present one or more graphical images on the display screen based on the wireless signals processed by the wireless transceiver using the sampling phase-locked loop.

33. The apparatus of claim 1, wherein:
the at least one switch is configured to open and close; and
the slope sampler is configured to close the at least one switch to sample the slope signal to secure the sampled signal.
